(19) United States
(12) Patent Application Publication
(10) Pub. No.: US 2024/0186768 A1
(43) Pub. Date: Jun. 6, 2024

(54) HIGH-DIMENSIONAL EVANESCENTLY COUPLED PHASE-LOCKED MICROLASER ARRAYS

(71) Applicant: THE TRUSTEES OF THE UNIVERSITY OF PENNSYLVANIA, Philadelphia, PA (US)

(72) Inventors: Liang FENG, Wynnewood, PA (US); Zihe GAO, Philadelphia, PA (US); Bikashkali MIDYA, Odisha (IN); Xingdu QIAO, Philadelphia, PA (US)

(21) Appl. No.: 18/556,519

(22) PCT Filed: Apr. 20, 2022
(86) PCT No.: PCT/US2022/071817

§ 371 Date: Oct. 20, 2023

Related U.S. Application Data
(60) Provisional application No. 63/177,680, filed on Apr. 21, 2021.

(51) Int. Cl. H01S 5/40; H01S 5/04; H01S 5/065; H01S 5/14

(52) U.S. Cl. CPC H01S 5/4075; H01S 5/041; H01S 5/0657; H01S 5/141

(57) ABSTRACT

Provided are systems and methods for high-dimensional phase-locked microlaser arrays. In embodiments, systems and methods can comprise a main array of light sources resonating in a plurality of energy levels, including a fundamental mode, at least one superpartner array of resonators positioned adjacent to the main array, and at least one auxiliary resonator. The superpartner arrays and the auxiliary resonators at least partially dissipate a subset of the plurality of energy levels emitted by the main array, except for the fundamental mode. In embodiments, the light sources can be microring lasers and/or electrically injected lasers.

### CROSS-REFERENCE TO RELATED APPLICATIONS

This application claims benefit under 35 U.S.C. § 119(e) of Provisional U.S. Patent Application No. 63/177,680, filed on Apr. 21, 2021, which application is incorporated herein by reference in its entirety for any and all purposes.

### GOVERNMENT RIGHTS

This invention was made with government support under 1932803, 1842612, 1936276, 1720530, 1542153 awarded by the National Science Foundation and W911NF-19-1-0249 and W911NF-18-1-0348 awarded by the Army. The government has certain rights in the invention.

### BACKGROUND

Single-mode high power lasers are highly desired, due to their high brightness, high intensity, and focus capabilities. However, both the design and output of such lasers extremely difficult to achieve. One seemingly straightforward method to achieve a single-mode high power laser is to couple multiple identical single-mode lasers together to form a laser array. Intuitively, such a laser array would have an enhanced emission power due to the increasing number of lasing elements. However, because of the nature of a coupled system, the laser array supports multiple transverse supermodes. When two lasers couple together, for example, they form 2 supermodes. When the laser array is large, such as an N×N array with N² individual lasers, there are N² supermodes, with closely spaced energy levels. This means that although high power laser could be obtained via the coupled array scheme, single mode operation becomes very difficult to achieve. The single mode operation is particularly challenging and desirable, because the radiance and brightness of the laser array increase with number of lasers only if they are mutually phase locked into a single supermode.

Moreover, current methods require “delicately designed ‘leakage’ of optical modes” to communicate between laser elements that limit the ability to downsize and densely package. The nonlinear scaling of complexity with the increased number of components in integrated photonics is a major obstacle impeding large-scale phase-locked laser arrays. Hence, how to achieve high power and single mode lasing simultaneously from a coupled laser array and how to develop a laser array that achieves not only the higher power but also greater radiance and brightness have become long-standing challenges.

### SUMMARY

Embodiments and advantages of the present invention include a two-dimensional (2D) array, such as a 5×5 array, that achieves higher power with single-fundamental-mode lasing with a very small divergence angle that can allow higher energy density and more precise beam steering. The method involves using several supersymmetric (SUSY) partners that match the resonance frequency of the main laser except for the lowest energy supermode. The lowest energy supermode is the fundamental supermode corresponding to in-phase operation. As such, lasers in the array can be locked to the same phase-achieving coherence. This is the first time it has been shown for 2D laser arrays.

Systems and methods further define the mathematics to create at least two superpartners. Together with 3 individual auxiliary partners (which, each, can also be regarded as a 1×1 superpartner array), e.g., micro-rings, (wherein two out of three have zero relative frequency detuning and the frequency of the last one matches the out-of-phase supermode with the highest relative frequency among all 25 transverse modes), the spectrum of superpartners is identical to the main array apart from the fundamental in-phase supermode. Strategically controlled coupling of the main array with its dissipative superpartners and auxiliary partner microrings, by matching both the eigen-frequencies and mode distributions, therefore ensures the suppression of all but the fundamental transverse supermode, yielding efficient single-supermode lasing.

A two-dimensional SUSY laser array is further capable of emitting vortex beam with topological charges. By matching the order of the angular grating with the order of the resonant mode, the total angular momentum associated with emission becomes zero, leading to the non-zero OAM of 1=±1 spin-orbit-locked with transverse spins of s=∓1 associated with the counterclockwise and clockwise modes in every microring, respectively. The desired phase variation and polarization distribution are collectively transferred to the laser beam emitted from the SUSY microlaser array, thereby facilitating single-frequency high-radiance vortex lasing with a factor of ˜20 in power enhancement. The technique can also be applicable to a 3D array.

The present disclosure describes systems and methods related to single-mode, high power optical signals, comprising: a main array of light sources resonating a plurality of energy levels, the plurality of energy levels including a fundamental mode, at least one superpartner array of optical resonators positioned adjacent to the main array, the at least one superpartner array of resonators configured to at least partially dissipate a subset of the plurality of energy levels emitted by the main array, wherein each subset does not include the fundamental mode; and at least one auxiliary resonator configured to further dissipate any remaining energy levels except for the fundamental mode.

In embodiments, the subset of the plurality of energy levels can be determined by applying a supersymmetry transformation on the main array of light sources. A supersymmetry transformation can also be applied on the at least one superpartner array. A combination of the at least one superpartner array and the at least one auxiliary optical resonators can be used to match eigenfrequencies and mode distributions of the main array. Likewise, a frequency of an auxiliary optical resonators can be matched with an out-of-phase supermode having a highest relative frequency among the plurality of energy levels using at least one auxiliary optical resonators.

In embodiments, the main array of light sources is an N×N or N×M array and the main array of light sources is a 5×5 array. Other embodiments can include two superpartner arrays and three auxiliary optical resonators. A first superpartner array can be an (N−2)×N array and a second superpartner array can be a 2×(N−2) array. In addition, a combination of the at least one superpartner array and the at least one auxiliary optical resonators match eigenfrequencies and mode distributions of the main array.

In various embodiments, there can be three auxiliary optical resonators, wherein two of the three auxiliary optical resonators have zero relative frequency detuning, and a frequency of the third auxiliary optical resonators matches an out-of-phase supermode with a highest relative frequency among the plurality of energy levels. Moreover, the subset of the plurality of energy levels can be determined by applying a supersymmetry transformation on the main array of light sources. The light sources in embodiments can be lasers, such as micro-ring lasers and/or electrically-injected lasers.

### BRIEF DESCRIPTION OF THE DRAWINGS

In the drawings, which are not necessarily drawn to scale, like numerals can describe similar components in different views. Like numerals having different letter suffixes can represent different instances of similar components. The drawings illustrate generally, by way of example, but not by way of limitation, various aspects discussed in the present document. In the drawings:

FIG. 1 is a schematic of a homogenously coupled two-dimensional array and its spectrum. FIG. 1A is a schematic of a 5×5 micro-ring laser array. FIG. 1B illustrates the corresponding spectrum of the 5×5 micro-ring array.

FIG. 2 illustrates a flowchart to synthesize SUSY partners.

FIG. 3 illustrates the generation of SUSY partners and the corresponding spectrum. FIG. 3A illustrates SUSY partner 1 and its spectrum. ω is the onsite energy (i.e., the frequency of the resonator) and κ is the coupling strength in the main array. Blue, solid lines in the spectrum represent the SUSY partner's energy levels. Red, dashed lines are the energy levels of the main array but eliminated in the SUSY partner 1. FIG. 3B SUSY partner 2 and its spectrum. Green, solid lines in the spectrum represent its energy levels. FIG. 3C illustrates 3 auxiliary rings with the corresponding energy level labeled in the same color as the ring. FIG. 3D illustrates a schematic of the main array coupled with all its lossy superpartners and the corresponding spectrum. η is the coupling strength between the main array and partners. The color of the ring array or ring corresponds to the energy levels in the same color.

FIG. 4 illustrates a 5×5 SUSY laser array design. FIG. 4A illustrates parameters and the spatial placement of the SUSY partners. FIG. 4B illustrates a simulation result of the coupling strength versus gap between adjacent rings. The arrows show the gap dimensions used in the final device design.

FIG. 5 illustrates laser intensity distribution in the main array, corresponding superpartner array, and in the main-superpartner coupled array, for selected few eigenfrequencies. It should be noted that lowest eigenfrequency ω−-2\sqrt{3}κ, corresponding to the fundamental mode, does not have any SUSY partner. The eigenfrequency ω−(\sqrt{3}−1)κ is 2-fold degenerate. The coupling between the main and superpartner array is observed (in the third column) when the superpartners are judiciously placed at the position of maximum mode overlap. The results presented here are obtained by COMSOL simulation.

FIG. 6 illustrates a comparison of linear spectra between a conventional array (i.e., the main array) and the SUSY array (i.e., main array coupled with dissipative superpartners). The design parameters used in this theoretical analysis are shown in FIG. 4A. Here the loss of κ/8 in all the superpartner elements is considered. The axes are normalized to κ.

FIG. 7 illustrates a fabrication flow of the 2D SUSY laser array.

FIG. 8 illustrates a schematic of the measurement set-up for the SUSY laser array. Green dots show the focal points of the lenses.

FIG. 9 illustrates a real part of the eigen values of the 48 supermodes regard to the loss on the SUSY partners (α). In the numerical calculation, the coupling strength inside the main array κ is taken to be 1, while the coupling strength between the main array and the SUSY partners η is set at 0.1. The loss on every microring inside the SUSY partners is αη, where α is a coefficient ranging from 0 to 2. The 48 supermodes are taken to 8 groups (corresponding to panel A-H) for better visualization. In each panel, the solid lines in the spectrum indicate the modes studied in the plot.

FIG. 10 illustrates an imaginary part of the eigen values of the 48 supermodes (β) regard to the loss on the SUSY partners (α). The imaginary parts of the supermodes are taken as βη, where η is the coupling strength between the main array and the SUSY partners and β is a coefficient. Other parameters in this numerical calculation are the same as those in FIG. 3. The 48 supermodes are taken to 8 groups (corresponding to panel A-H) for better visualization. In each panel, the solid lines in the spectrum indicate the modes studied in the plot.

FIG. 11 illustrates a spectrum when 2D SUSY laser array operates in the PT symmetry non-broken phase and PT symmetry broken phase. (A, B, C) are spectrum under three different pumping levels at 28 kW/cm², 30 kW/cm², 32 kW/cm², respectively. Top panels in (A, B, C) are when all the SUSY partners are suitably pumped. The device operates in the PT-symmetric phase, all the higher-order transverse modes are dissipated, and single fundamental supermode lasing is observed. Bottom panels in (A, B, C) are when the pumping on the SUSY partners are blocked by knife edges. The large gain-loss contrast make the device operate in the PT-broken phase, which causes the lossy SUSY partners to effectively decouple from the main array. Multimode lasing is therefore observed.

FIG. 12 illustrates a pumping profile (top panels) and the corresponding laser array spectra (bottom panels). The pumping profile is symmetric in x and y, and shows the cross sections. In top panels, the two red lines mark the boundary between the main array and the SUSY partner. FIG. 12A illustrates using a slightly defocused uniform pumping pattern with pump intensity gradually decaying into the SUSY partners, single fundamental mode lasing is observed; FIGS. 12B, 12C, and 12D illustrate increasing the pumping pattern size, multimode lasing is observed; FIG. 12E illustrates pumping only the main array, implemented with knife edges blocking the pump at the boundary, multimode lasing is observed, because excessive intrinsic loss in the SUSY partners decouples the partners from the main array.

FIG. 13 illustrates mode profiles of the two degenerate modes of the fundamental supermode in a 5×5 coupled microring array. FIGS. 13A and 13B illustrate intensity distributions of the electric field of the two degenerate modes in the array, respectively. FIGS. 13C and 13D illustrate intensity distributions of the electric field of the two degenerate modes in one individual ring, respectively. FIG. 13E illustrates the out-of-phase degenerate mode, where scatterers at the same position of two adjacent rings scatter light with opposite phase. FIG. 13F illustrates the in-phase degenerate mode, where scatterers at the same position of two adjacent rings scatter out light with the same phase. Arrows of the same color indicate the scatterers of the same position in each individual ring.

FIG. 14 illustrates an electric field of the in-phase and out-of-phase degenerate modes. FIG. 14A illustrates an Eₓ component of the in-phase degenerate mode. FIG. 14B illustrates an E_{y} component of the in-phase degenerate mode. FIG. 14C illustrates an Eₓ component of the out-of-phase degenerate mode. FIG. 14D illustrates an E_{y} component of the out-of-phase degenerate mode.

FIG. 15 illustrates a calculation of the far-field pattern. FIG. 15A illustrates a Far-field pattern of single ring with OAM 0. FIG. 15B illustrates Far-field patter of a 5×5 ring array oscillating collectively in phase, with OAM 0 from every ring. FIG. 15C illustrates far-field pattern of a 5×5 ring array oscillating collectively out of phase, with OAM 0 from every ring. Red circle in all the panels indicate the divergence angle of 0.4 rad, corresponding to the numerical aperture of the imaging system.

FIG. 16 illustrates a mode analysis of a single ring with N=32 and M=32. FIG. 16A illustrates the electric field intensity distribution of the degenerate mode with a standing wave where all the antinodes sit at the scatterers. FIG. 16B illustrates the electric field intensity distribution of the other degenerate mode with a standing wave where all the nodes are at the scatterers. FIG. 16C illustrates the corresponding Eₓ component of the degenerate mode in FIG. 16A where all the antinodes sit at the scatterers. FIG. 16D illustrates the corresponding E_{y} component of the degenerate mode in FIG. 16A where all the antinodes sit at the scatterers.

FIG. 17 illustrates the far-field pattern measured of a single ring laser with OAM±1. FIG. 17A illustrates the far-field pattern measured without a linear polarizer. FIG. 17B illustrates the far-field pattern measured with linear polarizer. The white arrows indicate the direction of the linear polarizer.

FIG. 18 illustrates the light-light curve of the SUSY laser array producing a high-radiance vortex beam (blue) and a single microring laser (red). The output power of a single ring is multiplied by 10 for better visualization.

FIG. 19 illustrates a calculation of the far-field pattern and 1D Fourier transform of the far-field. FIG. 19A is the phase distribution of OAM+1. FIG. 19B is a far-field pattern of a single ring with OAM+1. FIG. 19C is a far-field patter of a 5×5 ring array oscillating collectively in phase, with OAM+1 from every ring. FIG. 19D is a 1D Fourier transform along the vertical axis of the far-field pattern in FIG. 19C. Red circles in panels (FIG. 19B, 19C, 19D) indicate the divergence angle of 0.4 rad.

FIG. 20 is a calculation of the far-field pattern and 1D Fourier transform of the far-field. FIG. 20A is a phase distribution of OAM−1. FIG. 20B is a far-field pattern of single ring with OAM−1. FIG. 20C is a far-field patter of a 5×5 ring array oscillating collectively in phase, with OAM−1 from every ring. FIG. 20D is a 1-D Fourier transform along the vertical axis of the far-field pattern in FIG. 20C. Red circles in panels (FIGS. 20B, 20C, 20D) indicate the divergence angle of 0.4 rad.

FIG. 21 illustrates an exemplary higher-dimensional supersymmetric microlaser array, in accordance with embodiments discussed herein.

FIGS. 22A-22C illustrate an experimental characterization of a higher dimensional supersymmetric microlaser array, in accordance with embodiments discussed herein.

FIGS. 23A-23F illustrate a far-field characterization of laser emission of a higher-dimensional supersymmetric microlaser array, in accordance with embodiments discussed herein.

FIGS. 24A-24G illustrate a generation of high-radiance structured light, in accordance with embodiments discussed herein.

### DETAILED DESCRIPTION OF ILLUSTRATIVE EMBODIMENTS

The present disclosure can be understood more readily by reference to the following detailed description of desired embodiments and the examples included therein.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing. All publications, patent applications, patents and other references mentioned herein are incorporated by reference in their entirety. The materials, methods, and examples disclosed herein are illustrative only and not intended to be limiting.

The singular forms “a,” “an,” and “the” include plural referents unless the context clearly dictates otherwise.

As used in the specification and in the claims, the term “comprising” can include the embodiments “consisting of” and “consisting essentially of.” The terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of” the enumerated ingredients/steps, which allows the presence of only the named ingredients/steps, along with any impurities that might result therefrom, and excludes other ingredients/steps.

As used herein, the terms “about” and “at or about” mean that the amount or value in question can be the value designated some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Unless indicated to the contrary, the numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently of the endpoints. The endpoints of the ranges and any values disclosed herein are not limited to the precise range or value; they are sufficiently imprecise to include values approximating these ranges and/or values.

As used herein, approximating language can be applied to modify any quantitative representation that can vary without resulting in a change in the basic function to which it is related. Accordingly, a value modified by a term or terms, such as “about” and “substantially,” cannot be limited to the precise value specified, in some cases. In at least some instances, the approximating language can correspond to the precision of an instrument for measuring the value. The modifier “about” should also be considered as disclosing the range defined by the absolute values of the two endpoints. For example, the expression “from about 2 to about 4” also discloses the range “from 2 to 4.” The term “about” can refer to plus or minus 10% of the indicated number. For example, “about 10%” can indicate a range of 9% to 11%, and “about 1” can mean from 0.9-1.1. Other meanings of “about” can be apparent from the context, such as rounding off, so, for example “about 1” can also mean from 0.5 to 1.4. Further, the term “comprising” should be understood as having its open-ended meaning of “including,” but the term also includes the closed meaning of the term “consisting.” For example, a composition that comprises components A and B can be a composition that includes A, B, and other components, but can also be a composition made of A and B only. Any documents cited herein are incorporated by reference in their entireties for any and all purposes.

The present invention achieves a high-power, narrow-divergence, high-coherence lasers. Embodiments of the present invention present improvements over conventional technologies is to lock all the lasers in a laser array to the same phase, so that they have constructive interference, which narrows the beam divergence, increases the output power, and still maintain the coherence (e.g., spectral purity). The phase locking (also referred to as “single supermode lasing”) is challenging to achieve. Moreover, phase locking with in-phase operation (e.g., single fundamental supermode lasing) is much more challenging than having the lasers phase-locked to out-of-phase operation (e.g., 180 degree out of phase with its neighbors).

The present invention further provides an approach to achieve in-phase phase locking of a two-dimensional laser array. Methods and systems introduce supersymmetric partners (SUSY partners) to the laser array. The SUSY partners are dissipative and their resonance frequencies match the resonance frequencies of the main laser array, except for the lowest-energy supermode. The lowest energy supermode is the fundamental supermode corresponding to the in-phase operation, which is the desired supermode. Because of the dissipative SUSY partners that spoil all the high-order modes, the laser array operates exclusively in the fundamental supermode. This invention proposes a new formalism that can be applied to a two-dimensional laser array, which has not previously been accomplished, and have been experimentally demonstrated in a 5×5 microring laser array. Although various embodiments demonstrate an optically pumped microring laser array, the design can be used in any evanescently coupled laser arrays, including electrically pumped vertical cavity surface emitting lasers (VCSELs) that are widely deployed commercially. This idea can also be generalized to a three-dimensional array, as outlined herein.

In addition, 2D SUSY laser array embodiments show the capability to emit beams with orbital angular momentum or vector beam with spatial dependent polarization. Example applications of a beam carrying orbital angular momentum include OAM-multiplexed optical communication and optical tweezers.

Previous approaches to achieve in-phase laser array, such as anti-guided, diffractive, and antenna coupling required delicately designed “leakage” of optical modes to communicate between elements ultimately limiting their downsizing and dense packaging. The present invention's evanescently coupled laser array overcomes those challenges and can achieve denser integration and smaller form factor.

The present invention's high-power, narrow-divergence, high-coherence emitters can be used for LIDAR, optical sensing (for example, 3D sensing for consumer electronics and industrial applications, chemical sensing for environmental monitoring or security, etc.), material processing and manufacturing, heat-assisted magnetic recording, novel augmented-reality see-through displays, and any other application that requires high-brightness source (e.g., high power density in a certain solid angle). In addition, embodiments of the present invention can be further applied to applications and industries such as autonomous driving, computing, and laser manufacturing.

The principles discussed herein could be applied to electrically pumped lasers, possibly vertical cavity surface emitting lasers (VCSELs), or nanolasers, or photonic crystal lasers, as discussed below. In embodiments, tunability on the beam emitted by the 2D SUSY laser array can be further developed to focus on including the steering of the beam direction and orbital angular momentum (OAM) of the beam.

Embodiments of the present invention, e.g., the 2D SUSY laser array, has shown the capability of high-power, single-fundamental-mode lasing with small divergence angle. However, the direction of the emitted beam is fixed once the device is fabricated. Therefore, obtaining post-fabrication tunability of the beam direction on single-mode SUSY lasers is desired, as well as tunability of the OAM of the beam. In the current design, the OAM order carried by the emitted beam of an exemplary 2D SUSY laser array is determined by the grating orders inscribed along the inner side wall of the microring during fabrication. Hence, once the device is fabricated, the topological charge of the beam emitted is fixed. In order to get more degrees of freedom from the invention, post-fabrication tuning of the OAM orders of the device is desired. The tuning of OAM can be achieved by tuning the device temperature, or the pump level, for example.

Embodiments of the present disclosure create an ability to miniaturize and more densely populate lasers to a greater degree than anti-guided, diffractive, and antenna coupling methods currently used. As such, much denser laser arrays are possible. Such arrays are significant improvements compared to current methods, which often require “leakage” of optical modes to communicate between laser elements that limit an ability to downsize and densely package arrays. The present invention further allows capabilities to emit a laser beam with orbital angular momentum (OAM) or vector beam with spatial dependence, and with potential for beam steering. In embodiments, external optics can be implemented to collimate the beam or generate structured patterns. Such configurations can remove or minimize need for collimation optics.

In accordance with the present embodiments, the systems and methods discussed herein can be applied to electrically pumped lasers, vertical cavity surface emitting lasers, nanolasers, and other beam steering technologies. Additional applications include, but are not limited to optical sensing, use in LIDAR, 3D sensing in consumer electronics (e.g., telecommunications, smartphones, etc.), industrial applications, material processing (e.g., micromachining, cutting, welding, blazing, etc.), novel augmented reality (e.g., holographic displays, etc.), and photonic systems, such as those used for defense and aerospace.

Various embodiments of the present invention were inspired by the concept of supersymmetry (SUSY). Systems and methods are proposed to enforce single mode lasing in a laser array by adding a dissipative feature, called “superpartner”. The superpartner is generated by applying SUSY transformation on the laser array, and the resulting superpartner array automatically has all the energy levels except for the fundamental one. This kind of energy level correspondence is the essence of SUSY. When the SUSY partner array and the original laser array are coupled together, all the supermodes except for the fundamental mode will be dissipated, single fundamental mode lasing can therefore be achieved from the device.

Current SUSY arrays have been limited to a one-dimensional (1D) coupled laser array (i.e., a chain), as the original SUSY transformation in physics applies only to a 1D system, which is a major limitation. The present invention presents a significant improvement as it provides a generic method to generate the SUSY partners for a two-dimensional (2D) array and experimentally demonstrated it. For example, in an N×N coupled laser array, if the coupling is only along the axis and axis (i.e., there is no coupling in other directions, for example the diagonal direction), the two dimensions of that N×N laser array can be regarded as independent to each other. Applying the technique of ‘separation of variables’ to the laser array, the system can be decomposed into two 1D subsystems along the x-axis and the y-axis, respectively. Mathematically this is done by writing the 2D Hamiltonian of the laser array as a Kronecker sum of two 1D chains.

By applying multiple SUSY operations on the 1D subsystems, with a mathematically rigorous procedure discussed herein, the desired 2D superpartners can be obtained, with energy levels matching all the levels from the original laser array except for the fundamental one.

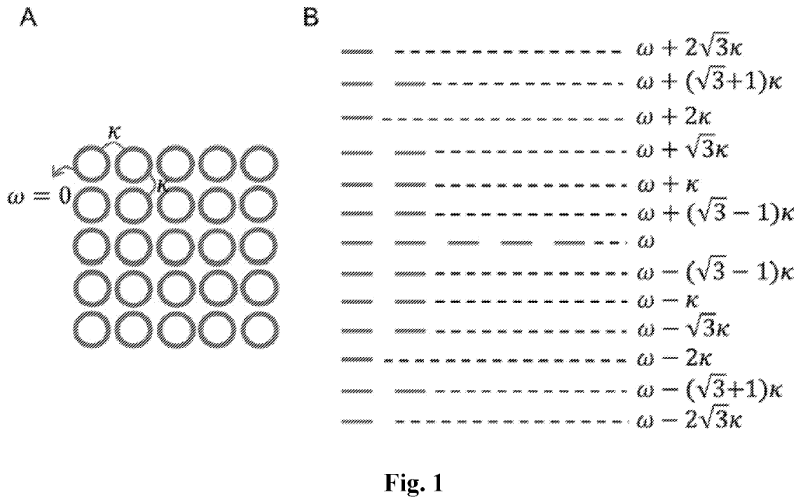

The specific process to generate a 5×5 2D SUSY laser array can be described as follows (see e.g., FIG. 1): The orthogonality inherently associated with the original a 5×5 system allows for separation of variables in the potential profile, so the Hamiltonian can be described in the form of a Kronecker sum,

H=Hₓ⊕H_{y}=Hₓ⊕I_{y}+Iₓ⊕H_{y}

Where ⊕ and ⊗ denotes the Kronecker sum and the tensor (Kronecker) product between matrices and H_{x,y}, represent 1D systems, consisting of 5 coupled resonators along the x and y direction with coupling strength Kₓ and K_{y}, and I_{y,x}, are 5×5 identity matrices. Here, the 2D isospectral superpartners can be configured using the tensor product based on two superpartners of Hₓ and H_{y}. Specifically, in contrast to non-negligible onsite frequency detuning across the superpartner array resulting from the first-order SUSY transformation, the second-order SUSY transformation is applied to yield a homogeneous superpartner array respecting the particle-hole symmetry and thus consisting of identical elements with the same resonant frequency compared with the main array, which is experimentally favorable especially for a large-scale system. To create a symmetric spectrum for the superpartner, in the second-order SUSY transformation two levels with the highest and lowest frequencies in the 1D Hamiltonian are eliminated (i.e., the matrix dimension of the SUSY partner of H_{x,y}, reduces from 5×5 to 3×3 in the present case). The SUSY transformation thus leads to two superpartner arrays: a 3×5 array with 15 transverse modes corresponding to H_{partner,1}=H_{x,s}^{(3×3)}I_{y}+Iₓ^{(3×3)}⊗H_{y}, where H_{x,s} is the second-order SUSY transformation of Hₓ; and a 2×3 array with 6 transverse modes corresponding to

H_{partner,2}=H_{x,r}^{(2×2)}⊗I_{y}^{(3×3)}+Iₓ^{(2×2)}⊗H_{y,s}^{(3×3)}, where H_{y,s} is the second-order SUSY transformation of H_{y} and H_{x,r}, (the “residual”) is an arbitrary 2×2 Hamiltonian that is isospectral to the energy levels originally in Hₓ, but eliminated in achieving H_{x,s}.

H_{x,r} can also be generated by a third-order SUSY transformation of Hₓ by deleting three modes apart from the first and last mode. Superscripts denote the dimensions of the matrices, and are not to be confused with the size of the resonator array. Together with 3 individual auxiliary partner microrings (2 out of 3 have zero relative frequency detuning and the frequency of the last one matches the out-of-phase supermode with the highest relative frequency among all 25 transverse modes), the spectrum of superpartners is identical to the main array apart from the fundamental in-phase supermode. Strategically controlled coupling of the main array with its dissipative superpartners and auxiliary partner microrings, by matching both the eigen-frequencies and mode distributions, therefore ensures the suppression of all but the fundamental transverse supermode, yielding efficient single-supermode lasing.

Equipped with this new method, a 2D SUSY laser array with microring lasers was designed and fabricated. The device is fabricated on 200 nm thick InGaAsP multiple quantum wells. The microring resonators were patterned with an inner radius of 3 μm and the width of the waveguide of 400 nm, operating at a resonance order of N=32 for the quasi-TE mode. To facilitate surface emission from microring lasers, an angular grating was inscribed on the inner sidewall of each mirroring. Emission from each scatterer in the angular grating is circularly polarized, resulting from the transverse spin in the evanescent region of the waveguide (i.e., the azimuthal and radial electric field components have π/2 phase difference). With the transverse spin (|s|=1), the order of the angular grating was designed as M=N−1=31, creating phase matching for equi-phase emission from all the scatterers on a microring carrying an orbital angular momentum (OAM) of l=0. When suitable pumping condition is applied on the 2D SUSY laser array, the device operates in single fundamental supermode. The fundamental mode, featuring the in-phase oscillation of all the lasing elements, shows a 25× increase of output power, and >100× increase in power density, as promised by a single mode laser array. This is the first demonstration of a 2D evanescently coupled laser array operating with single fundamental mode, due to the suppression of high order modes by the superpartners designed with this new method. Another employed technique, which is also critical to the experimental success, is the high-order SUSY transformation.

Furthermore, it has been demonstrated that the 2D SUSY laser array is capable of emitting vortex beam with topological charges. By matching the order of the angular grating with the order of the resonant mode (i.e., M=N=32), the total angular momentum associated with emission becomes zero, leading to the non-zero OAM of l=±1 spin-orbit-locked with transverse spins of s=∓1 associated with the counterclockwise and clockwise modes in every microring, respectively. The desired phase variation and polarization distribution are collectively transferred to the laser beam emitted from the SUSY microlaser array, thereby facilitating single-frequency high-radiance vortex lasing with a factor of ˜20 in power enhancement. With the single fundamental mode operation forced by the SUSY partners, all the lasing element with the same topological charge will oscillate in phase and interfere constructively at the far field. High power, single mode lasing with desired OAM order can therefore be achieved.

In summary, the discussed 2D SUSY scheme provides a generic method to obtain single-mode high power lasing from evanescently coupled laser arrays, which is highly demanded and actively pursued for a wide range of applications, including optical communication, optical sensing, and LIDAR ranging. Bringing the SUSY scheme to 2D constitutes a powerful toolbox for potential large-scale integrated photonic systems.

### 1. Linear Spectral Analysis of the Main Array

In accordance with embodiments of the present invention, a homogeneously coupled 2D array of N×N identical microrings can be considered, where N is the total number of rings in each orthogonal direction. The onsite energy of each microring is considered to be the resonant frequency of ω, and the coupling between two adjacent rings is κₓ=κ_{y}=κ, as shown in Fig. S1A. The tight-binding Hamiltonian of the system can be written as a N²×N² matrix [Hᵢⱼ]

$$H = {\sum }_{i , j} {a}_{i}^{†} {H}_{ij} {a}_{j}$$

where i, j∈{1, . . . , N²}represent the index of the rings, respectively. The index j in aj is related to the double index (m, n) [see Eq. 1 of main text] by j=N(m−1)+n. The diagonal elements of the Hamiltonian matrix represent the onsite energy (as well as gain and loss), and off-diagonal elements corresponds to the coupling amplitude between different elements in the array. In a frame of reference which is rotating with angular frequency equal to co, the diagonal element of the Hamiltonian becomes zero. Therefore, without loss of generality, one can consider ω=0. The spectrum of the system's Hamiltonian can be calculated by diagonalizing the matrix [Hᵢⱼ]. In particular, for a 5×5 array, the spectrum (shown in FIG. 1B) has 25 transverse supermodes with 13 eigen frequencies; this spectral degeneracy is due to the 4-fold rotational symmetry of the square array. The in-phase transverse mode is the supermode with the lowest frequency, ω−2√3κ. Among the eigenmodes the one with the lowest frequency (i.e., ω−2√3κ) corresponds to in-phase transverse mode implying that all rings in the array oscillates in phase.

### 2. Synthesis of the SUSY Partners

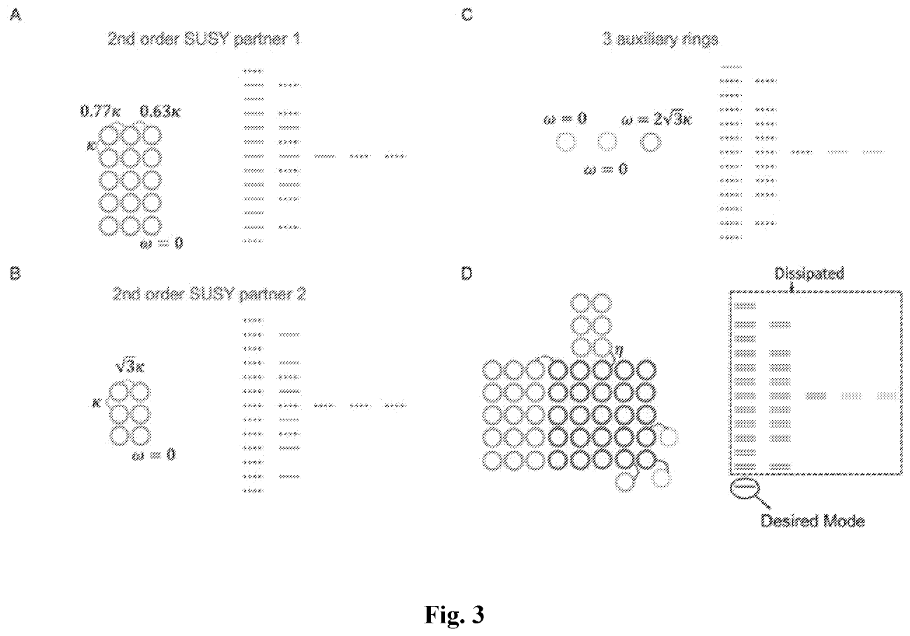

Here, a systematic procedure is developed to construct 2D SUSY partner arrays corresponding to a given 2D main array. The superpartner arrays are constructed such that the modes (including degenerate ones) of the superpartners are isospectral to those of a main array apart from the fundamental in-phase mode which is deleted by SUSY transformations. The design flow to achieve the SUSY partners of the main array is shown in Fig. S, with detailed spectra of SUSY partners exemplified in FIG. 3.

The Hamiltonian of the main array can be described in the form of a Kronecker sum:

H=Hₓ⊕H_{y}=Hₓ⊗I_{y}+Iₓ⊗H_{y}

where Hₓ and H_{y} can be written explicitly as:

$${H}_{x} = {H}_{y} = ( \begin{matrix}0 & κ & 0 & 0 & 0 \\ κ & 0 & κ & 0 & 0 \\ 0 & κ & 0 & κ & 0 \\ 0 & 0 & κ & 0 & κ \\ 0 & 0 & 0 & κ & 0\end{matrix} ) .$$

The separability of the 2D Hamiltonian in terms of 1D Hamiltonian implies that the isospectral partner of the main array then can be obtained by applying the discrete SUSY transformations on each of the 1D arrays. The superpartners can be synthesized based on higher-order SUSY. Higher-order SUSY transformation of k-th order relies on the consecutive applications of single SUSY transformations k-times by deleting total k-eigenmodes (9). Higher-order SUSY transformations which eliminate positive and negative eigenfrequencies (including zero eigenvalue) of equal magnitudes ensuring that the spectrum of the resulting higher-order superpartner is particle-hole symmetric. The chiral symmetry also implies that all the diagonal elements of the superpartner Hamiltonian is zero, and thus enables one to design the superpartner rings having geometry identical to the main array rings. For a 5×5 main array, one obtains following five decoupled partners which are isospectral to the main array apart from the fundamental mode.

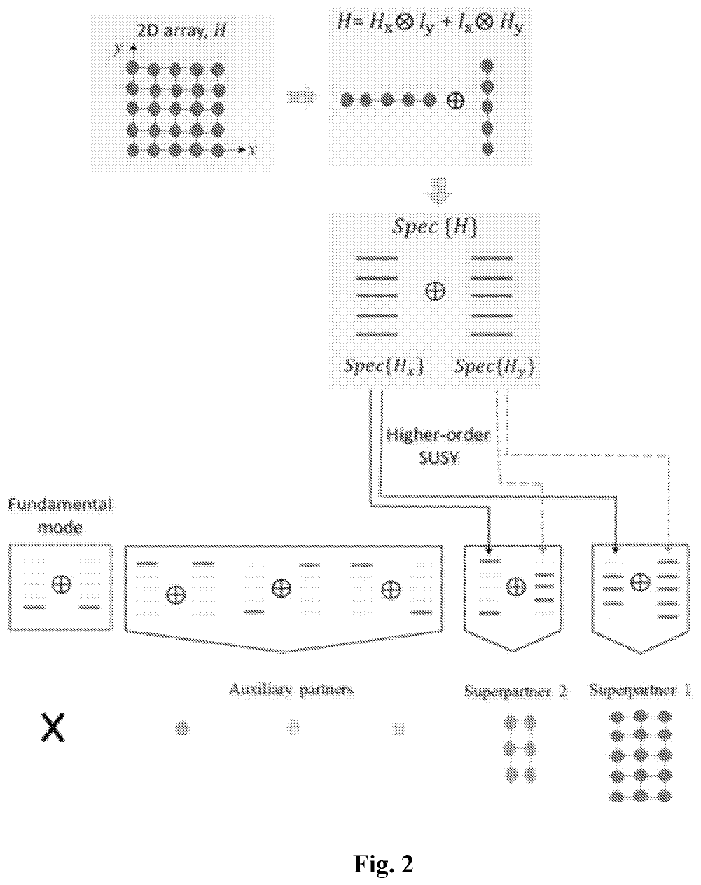

Superpartner 1: This 3×5 partner is obtained by taking Kronecker sum between the second-order SUSY partner H_{x,s} of Hₓ and the Hamiltonian H_{y} to which no SUSY has been applied (FIG. 2). The second-order SUSY partner H_{x,s} of Hₓ can be obtained by consecutively applying the discrete SUSY transformation (QR factorization) on Hₓ twice, after eliminating the largest and smallest eigenfrequency in the spectrum (9):

$${H}_{x , s} = - ( \begin{matrix}0 & 0.63 κ & 0 \\ 0.63 κ & 0 & 0.77 κ \\ 0 & 0.77 κ & 0\end{matrix} )$$

H_{x,s} is isospectral to Hₓ except for the highest and lowest eigen frequencies of Hₓ. Thus

H_{partner,1}=H_{x,s}^{(3×3)}⊗I_{y}+Iₓ^{(3×3)}⊗H_{Y}

With Spec{H_{partner,1}}=Spec{H_{x,s}}⊕Spec{H_{y}}.

Superpartner 2: This SUSY partner of array dimension 2×3 can be obtained by the Kronecker sum between third-order SUSY partner of Hₓ and second-order SUSY partner of H_{y} (FIG. 2). The third order SUSY partner of Hx (which is obtained after deleting all three eigenfrequencies but the largest and smallest ones) can also be easily constructed as 2×2 matrix H_{x,r} that is isospectral to the energy levels originally in Hx but eliminated in obtaining H_{x,s}:

$${H}_{x , r} = ( \begin{matrix}0 & \sqrt{3} κ \\ \sqrt{3 κ} & 0\end{matrix} ) .$$

On the other hand, 2^{nd} order SUSY partner H_{y,s} of H_{y} is identical to H_{x,s} obtained earlier. Therefore

H_{partner,2}=H_{x,r}^{(2×2)}⊗I_{y}^{(3×3)}+Iₓ^{(2×2)}⊗H_{y,x}^{(3×3)}

with Spec{H_{partner,2}}=Spec{H_{x,r}}⊕Spec{H_{y,s}}.

Auxiliary partners: Other three partners consist of single decoupled elements in the array each isospectral to single eigenfrequency levels of the main array (FIG. 2). Two of the auxiliary partners are corresponds to eigenfrequency Co that is equal to the resonance frequency of the main array elements in isolation; whereas another auxiliary partner have eigenfrequency equal to ω+2\sqrt{3}κ.

The SUSY partners so obtained are isospectral to the main array apart from the lowest frequency, that is the fundamental mode which does not have any superpartner.

Super-partner for an N×N array: Note here that although 2D SUSY has been considered with regard to a 5×5 array as a proof of principle demonstration of higher-dimensional SUSY laser array operating at fundamental in-phase mode, the systematic approach developed here can readily be applicable to any coupled system described by a Hamiltonian which is separable in terms of Kronecker sum of 1D array Hamiltonians.

To achieve single fundamental-mode lasing in an arbitrary N×N array, superpartners should be synthesized isospectral to the main array (apart from the in-phase mode), and can be achieved by the following generalizations of the theory developed for the 5×5 array.

The superpartner of an N×N array consists of five decoupled arrays: two superpartners, one with array dimension of (N−2)×N, another superpartner of dimension of 2×(N−2), and three uncoupled auxiliary rings.

The largest superpartner can be synthesized by the Kronecker sum of the 2nd order SUSY transformed 1D Hamiltonian (after deleting positive and negative eigenfrequencies of largest magnitude) along the x direction and the untransformed Hamiltonian along the y direction. The superpartner thus obtained has array dimension equal to (N−2)×N.

The second superpartner array corresponds to the Kronecker sum of the (N−2)-th order SUSY transformed 1D Hamiltonian along the x direction after eliminating all the eigenfrequencies but the smallest and largest one (also called the residual Hamiltonian as it contains only the 2 eigenvalues that were not eliminated in the previous step) and the 2nd order SUSY transformed Hamiltonian (after deleting positive and negative eigenfrequencies of largest magnitude) along y-direction. The superpartner thus obtained has array dimension equal to 2×(N−2).

One of the auxiliary rings have the resonance frequency equal to the largest eigenfrequency of the N×N main array (while other two auxiliary rings are identical to main array rings, similar to 5×5 case).

Final geometry for the main and superpartner coupled system has to be judiciously determined by the spatial distribution of the eigenmode intensities. For efficient laser operation, one needs to couple the superpartners and auxiliary rings with the main array at the position facilitating maximum mode overlaps.

Note that such an approach detailed above can be further generalized to a N×N×N cubic array in 3D, producing 3 partner arrays of (N−2)×N×N, 2×(N−2)×N, 2×2×(N−2), respectively, and 7 auxiliary rings. When the superpartners are dissipative and coupled to the main array, all the higher-order transverse modes are dissipated but the fundamental supermode which is isolated from the partners (Fig. SM).

FIG. 2 illustrates the above concepts and depicts a flowchart to synthesize SUSY partners. The Hamiltonian matrix H of the 2D 5×5 array can be written in terms of the Kronecker sum of the Hamiltonian matrices of the 1D 1×5 array along the x and y directions, denoted as Hₓ and H_{y}, respectively. The SUSY partners of the 2D 5×5 array can therefore be constructed by the Kronecker sum of the higher-order superartners of the 1D 1×5 arrays. Solid lines in the spectrum mean the energy levels that are kept after SUSY transformation and dashed lines indicate the energy levels deleted by the SUSY transformation. The isospectral partner of the main 2D array consists of 5 de coupled arrays: superpartner 1 of array dimension 3×5 (obtained after second-order SUSY transformation to Hₓ), superpartner 2 of array dimension 2×3 (obtained after third-order SUSY transformations to Hₓ and second-order SUSY transformation to H_{y}), and three auxiliary partners each with single elements. The fundamental mode of the main array does not have any superpartner.

### 3. Design and Simulation for the SUSY Laser Array

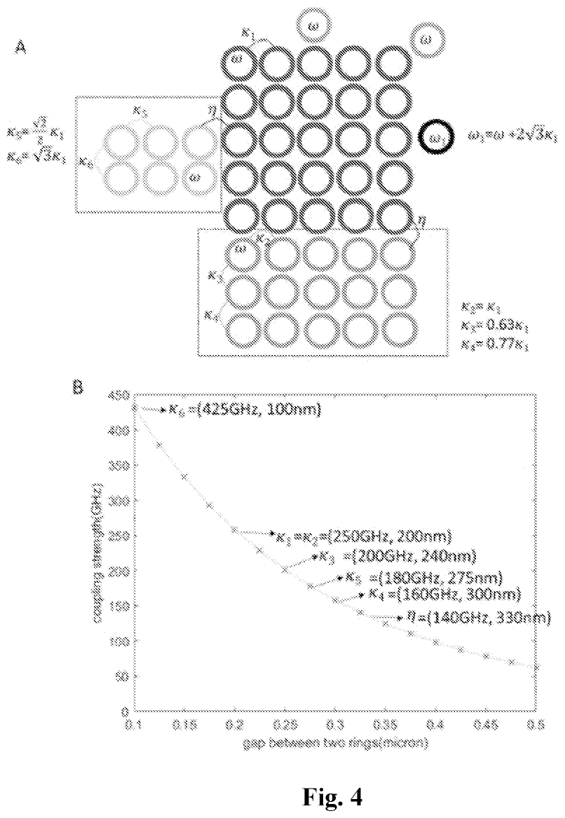

The Hamiltonian matrices generated from SUSY transformations are used to determine the coupling strengths in SUSY partners, as shown in FIGS. 3 and 4A. Finite element method (FEM) simulation was used to determine the gaps between rings, which yields such coupling strengths, shown in FIG. 4B. The SUSY array was placed judiciously according to the mode profile of the supermodes such that the SUSY partner mode has large overlap with the mode it dissipates. Experimentally, the spectral splitting in a two-ring array with varying gap between the two rings were measured and coupling strengths were observed to be consistent with the simulation in FIG. 4B.

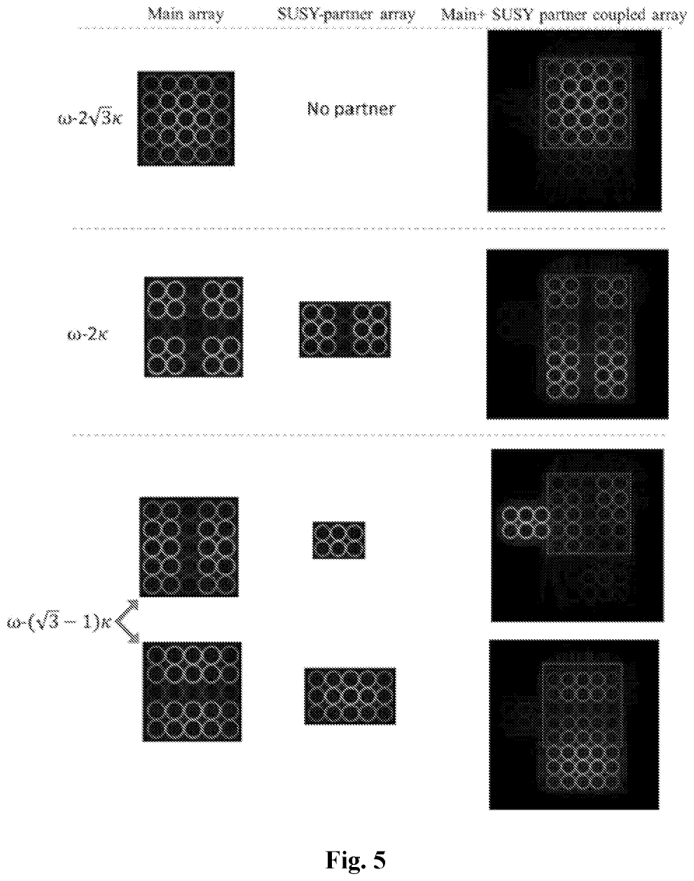

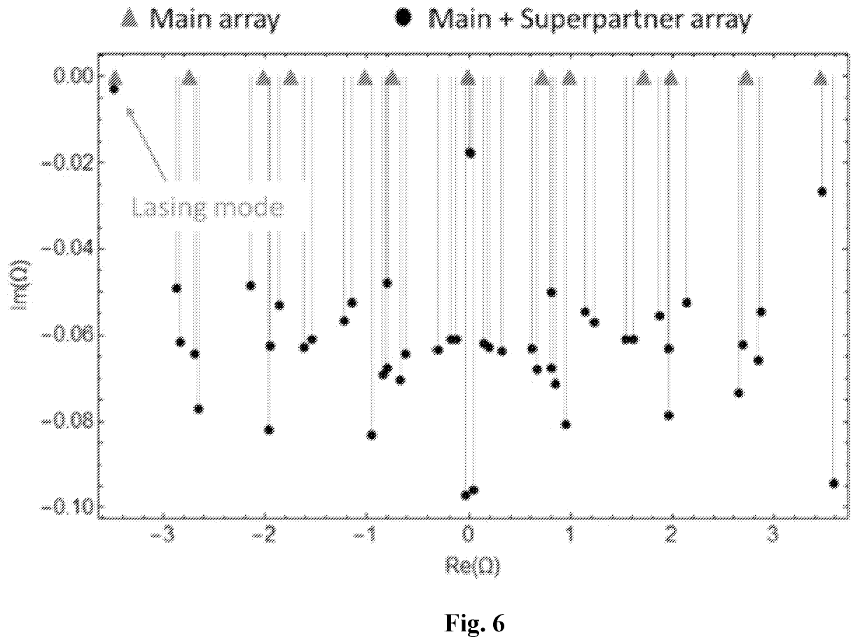

FEM simulations using COMSOL are shown in FIG. 5 to illustrate the judicious spatial placing of SUSY partner and the matching of spatial profiles between main array supermodes and partner supermodes. To verify the desired suppression of high-order supermodes, the spectrum of all the supermodes using the tight binding Hamiltonian (FIG. 6) were calculated where the vertical axis shows the fundamental mode having the lowest loss.

### 4. Sample Fabrication

The devices were fabricated using standard nanofabrication techniques. Hydrogen silsesquioxane (HSQ) solution in methyl isobutyl ketone (MIBK) was used as negative electron beam lithography resist. The concentration ratio of HSQ (FOX 15) and MIBK was adjusted such that after exposure and development the resist was sufficiently thick as an etching mask for the subsequent etching process. The resist was then soft baked and the structure was written by electron beam exposure. Electrons convert HSQ resist to an amorphous structure similar to SiO2. The patterned wafer was then immersed and slightly stirred in tetramethylammonium hydroxide (TMAH) solution (MFCD-26) for 120 seconds and rinsed in DI water for 60 seconds. The exposed and developed HSQ served as a mask for the subsequent inductively coupled plasma etching process that uses BCl₃:Ar plasma with gas ratio of 15:5 sccm respectively with RF power of 50 W and ICP power of 300 W under a chamber pressure of 5 mT. After dry etching, HSQ resist was removed by immersing the sample in buffered oxide etchant (BOE).

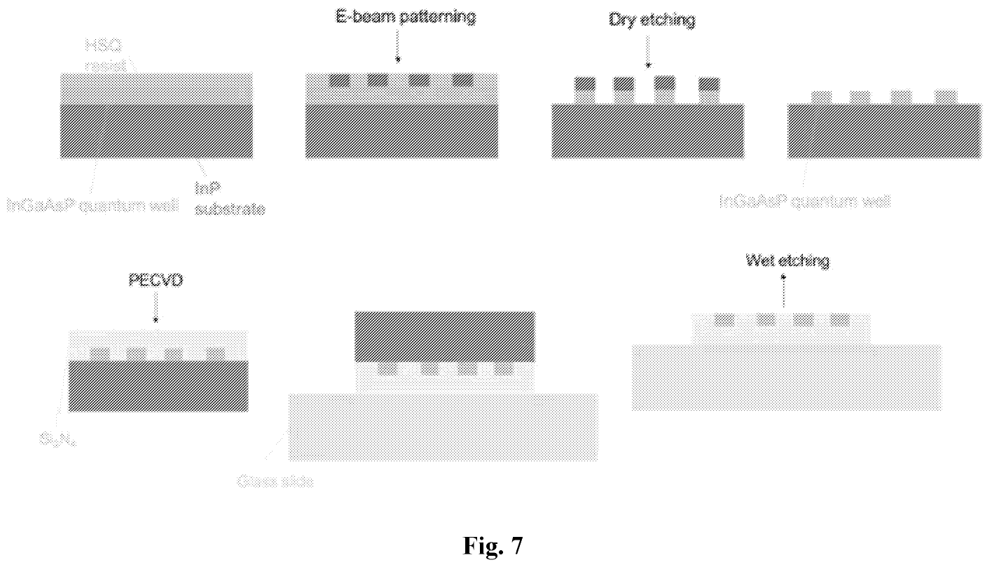

To overcome inevitable ring-to-ring non-uniformity at the nanoscale across the whole device due to fabrication imperfection, the sample was subsequently covered with a cladding layer of Si3N4 using PECVD to enhance the evanescent coupling strengths to ensure uniform nearest couplings despite slight frequency detuning (<1 nm). The wafer was then bonded to a glass slide which functions as a holder. Finally, the InP substrate was removed by wet etching with a mixture of HCl (Hydrochloride acid) and H₃PO₄ (Phosphoric acid) (FIG. 7).

### 5. Optical Measurement of SUSY Laser Arrays

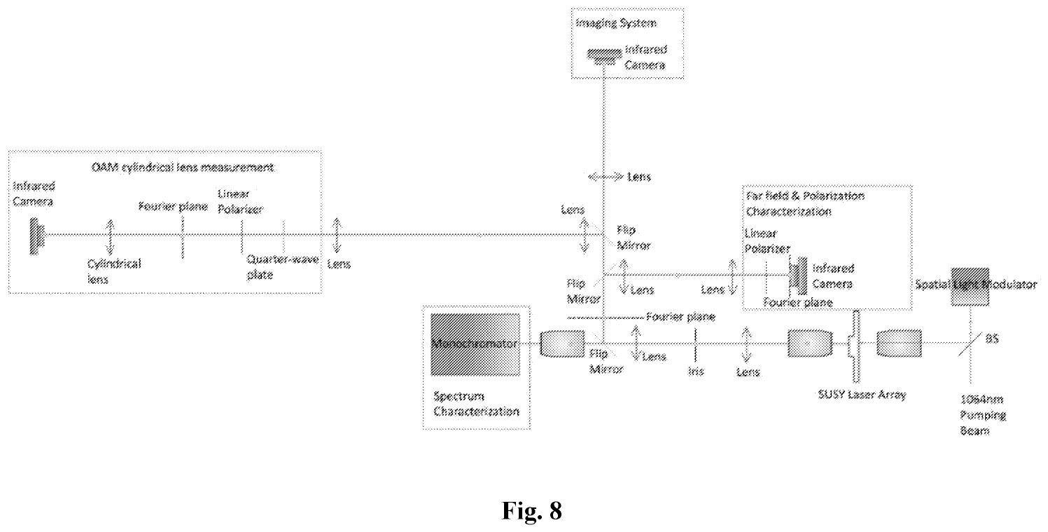

FIG. 8 shows the measurement setup used to obtain the laser spectra, far-field patterns, and to examine the polarization states of laser emission. The fabricated SUSY laser array was pumped on the back side by a nanosecond pulsed laser with a 50 kHz repetition rate and 8 ns pulse duration at the wavelength of 1064 nm. The pump power was controlled with a variable neural density (ND) filter and the pump pattern was generated via a spatial light modulator. The pump beam was focused onto the SUSY laser array using a Mitutoyo 10× near infrared (NIR) long working distance objective (NA=0.28) from the backside. The laser emission from the front side was collected by a Mitutoyo 20x NIR long-working distance objective (NA=0.4), guided into a monochromator for spectral analysis in the 1450-1550 nm range. The far-field pattern of the beam was also characterized by taking the image at the Fourier plane of the imaging system using an infrared camera, and the polarization response was obtained by passing the beam through combinations of a linear polarizer and a quarter-wave plate. The images of the emission at the sample plane were taken at the imaging plane of the imaging system.

### 6. Parity-Time (PT) Symmetry Analysis of the 2D SUSY Microring Arrays

When the main array is coupled to its dissipative, isospectral SUSY partners, the degeneracy would be lifted and every supermode thus splits into two loss modes except for the fundamental mode due to the absence of a SUSY partner at its frequency (Fig. S31)). For now, considering n, the ring-ring coupling strength between the SUSY partners and the main array (Figs. S31) and S4A), to be an order of magnitude smaller than κ, where coupled supermode pairs to illustrate the PT symmetry and Eps can be easily identified. It can be shown that excessive loss breaks the PT symmetry and decoupled the superpartners from the main array. In addition it can be shown that similar PT breaking when η is comparable to κ, which corresponds to the loss-induced decoupling experimentally observed when using knife edges to create sharply terminated pumping pattern covering only the main array. This is why pumping intensity profiles gradually decaying into the superpartners to successfully demonstrate single-mode SUSY laser have been used.

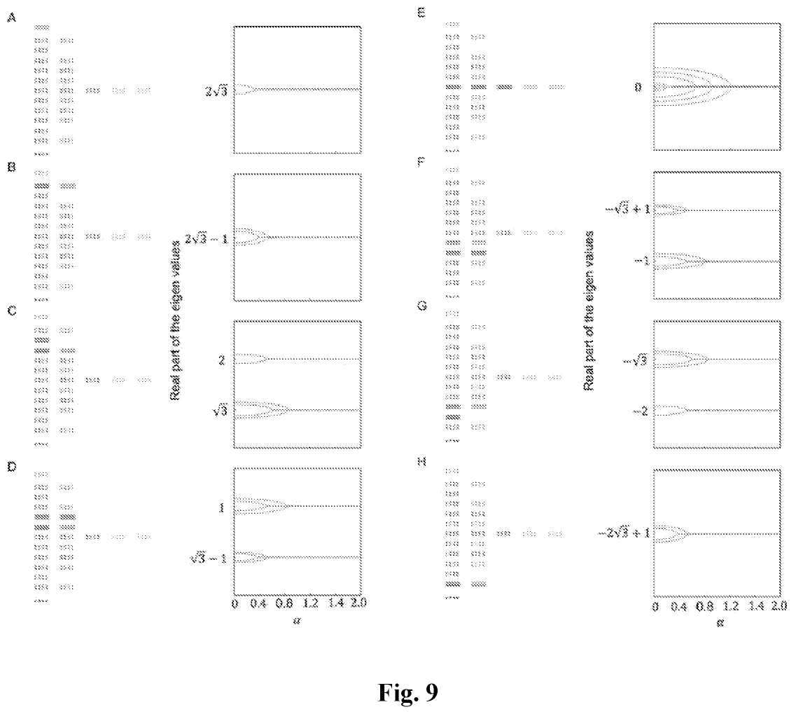

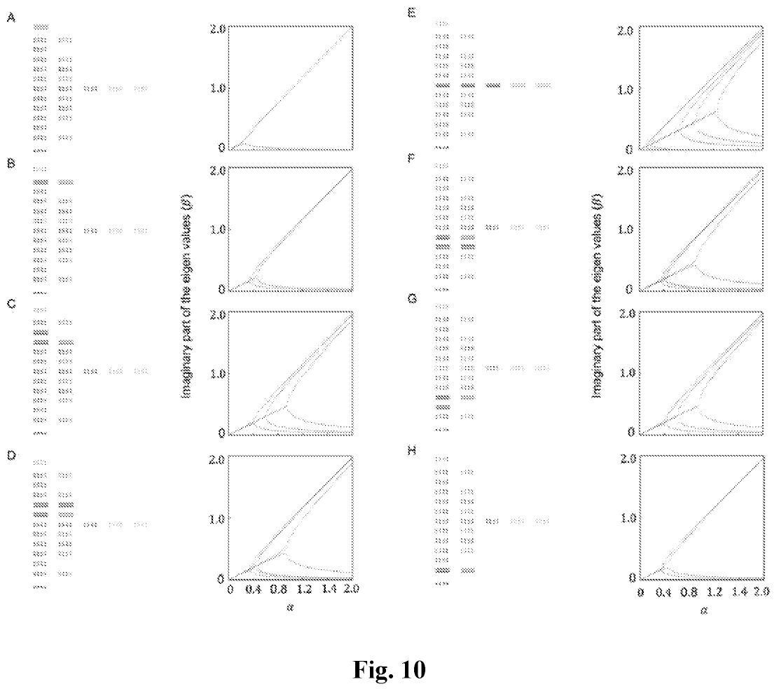

In the case of η=0.1κ, for example, each of the original 24 higher-order transverse supermodes splits into a closely-spaced pair, and the whole SUSY laser array possesses 49 supermodes: the aforementioned 24 pairs plus 1 fundamental mode. To ensure that the unwanted 48 modes can be sufficiently dissipated, it is necessary to ensure the 2D SUSY laser array to operate in the PT-symmetric phase. In other words, the gain-loss contrast between the main array and the super partners cannot be too large, otherwise they become decoupled from each other due to spontaneous PT symmetry breaking, resulting in reduced dissipation to the undesired high-order modes. The loss in every element of the SUSY partners to be αη can be considered. By calculating the eigenvalues of the tight-binding Hamiltonian of the whole SUSY laser array, the PT-symmetric condition of the 48 dissipative supermodes can be obtained. The real parts and imaginary parts of the 48 eigenvalues are shown in FIG. 9 and FIG. 10, respectively. In order to have all the 48 supermodes operate in the PT-symmetric phase, the maximum loss on each element of the SUSY partners cannot be higher than ˜ 1/10 the coupling strength between the main array and the SUSY partners (Figs. S9E, Fig. S10E).

In FIGS. 9E and 10E, the exceptional points (EPs) where the two eigenvalue branches of a pair of coupled supermodes collide can be identified. The value of αη/2 at the EP can be regarded as the effective coupling between the supermode and its SUSY partner, which is different for each supermode-partner pair and is dependent on the spatial placement of the partner array. The location of partner arrays have been judiciously chosen to achieve large enough effective coupling for efficient suppression of unwanted supermodes, as explained in Section 3 and FIG. 5.

For every pair of the supermode, the condition for PT-symmetry breaking is calculated by gradually increasing the loss on the superpartners. FIGS. 9 and 10 show that, before the EP the two supermodes in every mode pair are in the PT-symmetric phase and their eigen values split in the real part while share the same imaginary part. However, when the loss on the superpartners increases, the real parts of the eigenvalues gradually converge and finally reach EP. Beyond EP, the imaginary parts of the eigen values bifurcate while the real parts merge into one. Note that because of the different effective coupling strengths, the loss needed to break the PT-symmetry of different supermode pairs is different. In order to make the device function in the PT-symmetric phase, it is necessary to consider the effective coupling strengths of the supermodes between the main array and the SUSY partners. In short, it has been illustrated that excessive loss in the superpartners breaks the PT symmetry, effectively decoupling the superpartners from the main array, and reducing the loss seen by the high-order supermode in the main array, which is undesirable. It is desirable to carefully control the loss in the superpartners to prevent severe decoupling from the main array due to PT symmetry breaking.

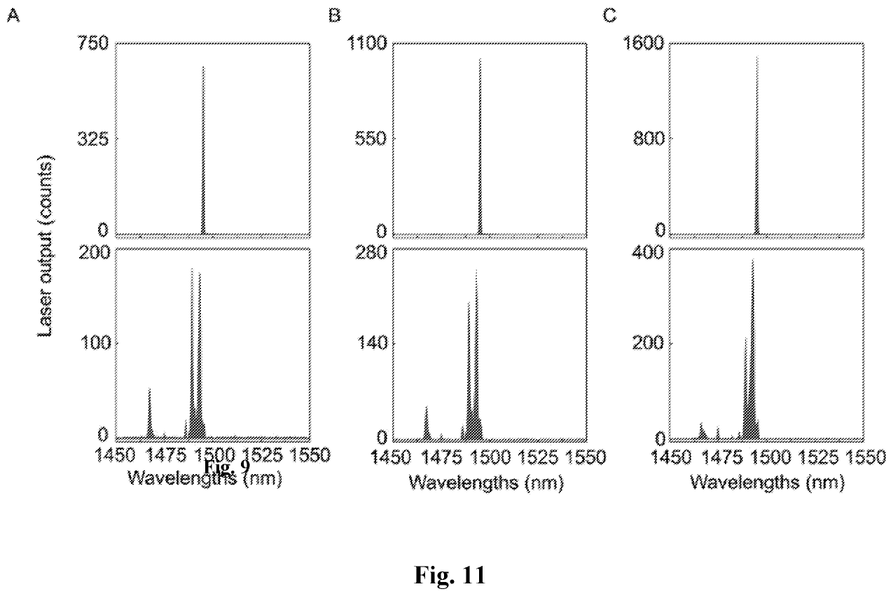

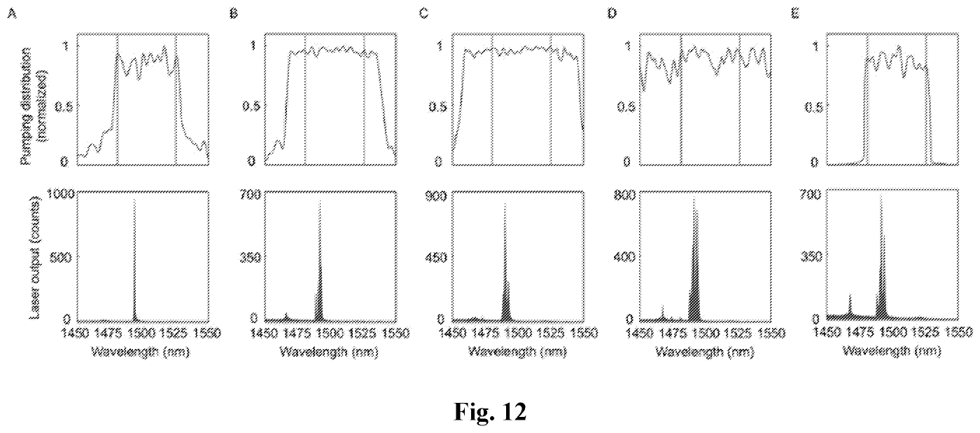

The intrinsic material loss on the fabricated SUSY partners is estimated to be ˜500 GHz while the coupling strength between the main array and the SUSY partners is designed to be ˜150 GHz. This loss is large enough to severely decouple the SUSY partner from the main array. Therefore, in order to prevent the SUSY partners from decoupling from the main array (i.e., entering the PT-broken phase), it is critical to keep the SUSY partners slightly pumped such that the gain-loss contrast between the main array and SUSY partners stays in the PT-symmetric phase while the partners still remain dissipative. In experiments, this was realized by having the pump light gradually decaying into the surrounding SUSY partners, implemented by a spatial light modulator-controlled defocused pump pattern. A control experiment was carried out by sharply blocking the intensity extension into the SUSY partners using knife edges. In this control experiment, the strong gain-loss contrast arising from the sharp pumping intensity decrease between the main array and SUSY partners make the system operate in the PT broken phase, thus leading to mode competition and a multimode lasing spectrum (FIG. 11). More detailed evolution of lasing spectra as a function of pumping profiles can be seen in FIG. 12.

### 7. Numerical Calculation of the Far-Field Emission Pattern

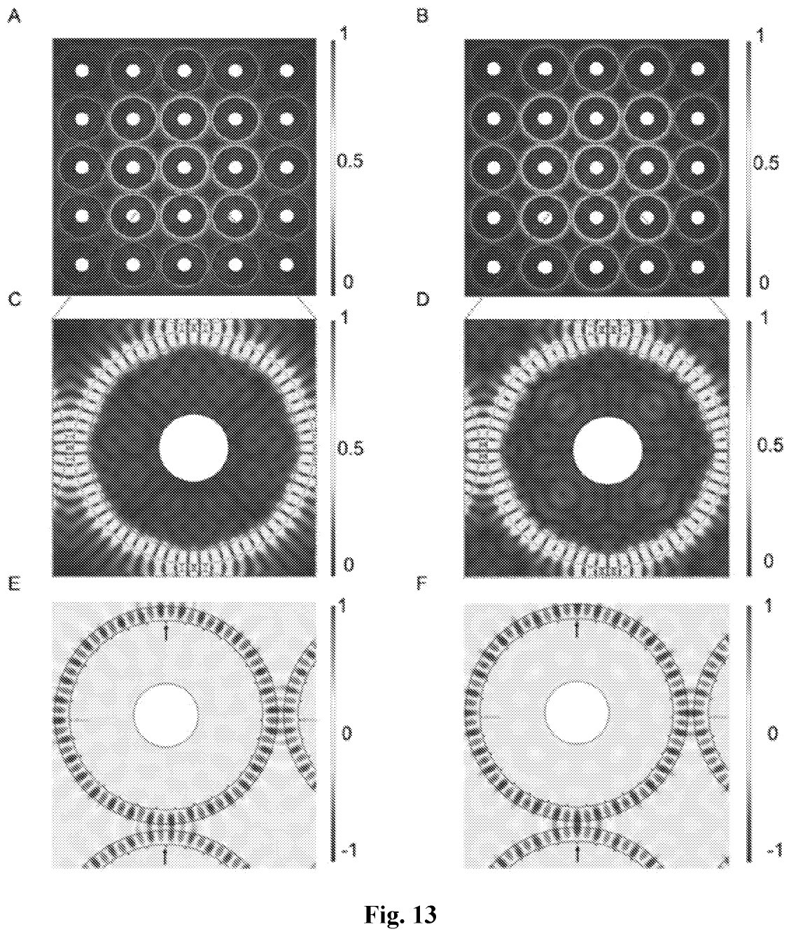

In the design of the 2D SUSY laser array, the mode order inside each single ring cavity is N=32. With angular gratings at order M=31 inscribed along the inner sidewall of each ring, the emission of a beam with an orbital angular momentum (OAM) of l=0 can be obtained because of the designed transverse spin (|s|=1). In the OAM 0 SUSY laser array, every individual ring inside the 5×5 main array was designed with N=32 and M=31. Due to the coexistence of degenerate clockwise (CW) and counterclockwise (CCW) whispering gallery modes in each ring, the fundamental supermode of the 5×5 coupled microring array has a twofold degeneracy as a result of the twofold degeneracy of each ring (FIGS. 13A and 13B). These two degenerate modes, with details shown in FIGS. 13C and 13D, are standing waves as CW+CCW and CW−CCW, respectively. The out-of-plane magnetic field distributions (FIGS. 13E and 13F) indicate the phase information inside the ring array. If only the emission from the inscribed scatterers is considered, it can be seen from the numerical simulation that for one degenerate mode (FIG. 13E), the emissions from the scatters at the same position of adjacent rings have opposite phase, while for the other degenerate mode (FIG. 13F), the emissions from the scatters at the same location of every individual ring have the same phase. This indicates that the fundamental transverse supermode in the array have both in-phase and out-of-phase emission owing to the twofold degeneracy fundamentally associated with each ring.

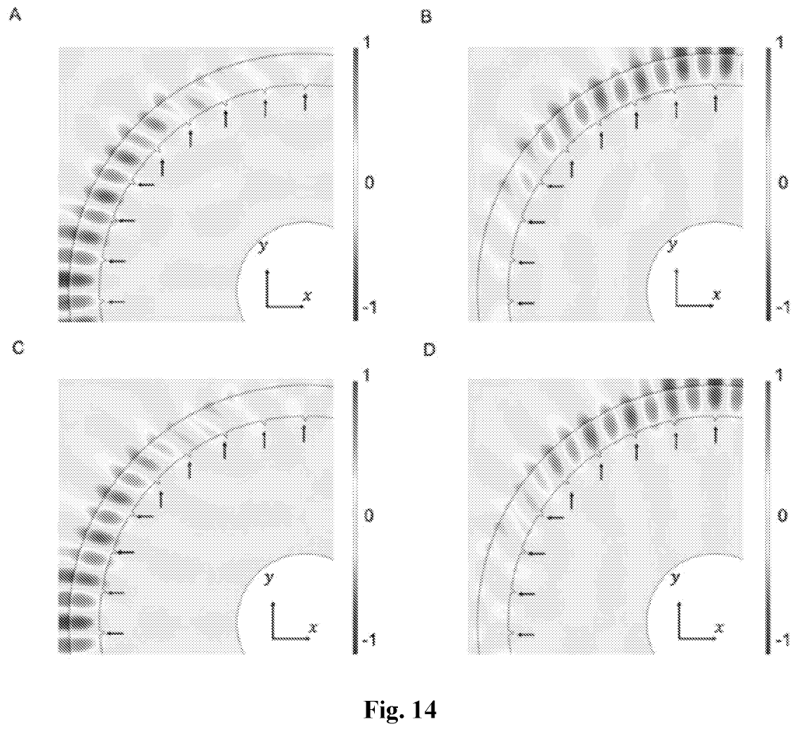

Additionally, the in-phase and out-of-phase degenerate modes carry two different orthogonal polarizations, respectively. The numerical simulation result shows that at every scatterer of the in-phase degenerate mode, the Eₓ component has a nonzero field distribution (FIG. 14A) while for E_{y} it is always vanishing (FIG. 14B), leading to x-polarized emission. On the contrary, for the out-of-phase degenerate mode, Eₓ is always 0 (FIG. 14C) and E_{y} has a nonzero field distribution at every scatterer (FIG. 14D), leading to y-polarized emission. Therefore, by applying a linear polarizer, the in-phase and out-of-phase mode can be distinguished, as shown in FIGS. 3E and 3F in the main text.

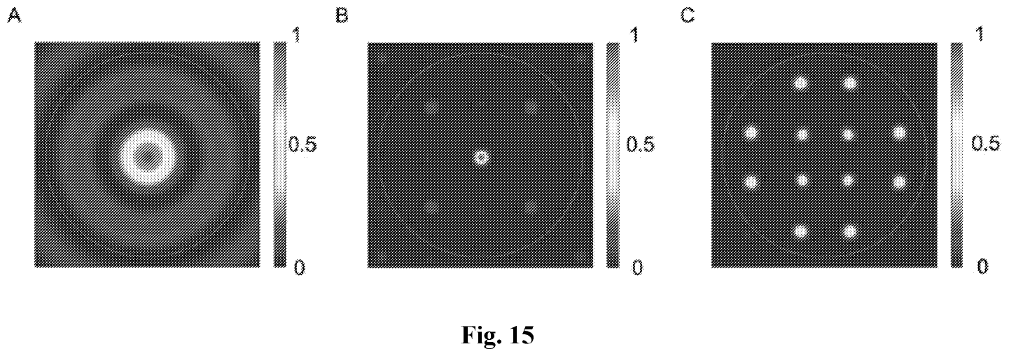

The far-field calculation of a single ring is shown in FIG. 15A. When the 2D SUSY laser operates in the single fundamental supermode, 25 rings with OAM emission 0 collectively oscillate in phase, and the calculation result of the far-field pattern is shown in FIG. 15B, consistent with the result shown in FIG. 3E. The far-field pattern still shows a bright spot in the center, but with a much narrower divergence angle compared to that of a single ring. On the contrary, when 25 rings of OAM emission 0 oscillate out of phase, the far-field pattern has a dark center, shown in FIG. 15C which is consistent with FIG. 3F.

### 8. Vortex Laser Emission From Individual Microring Lasers

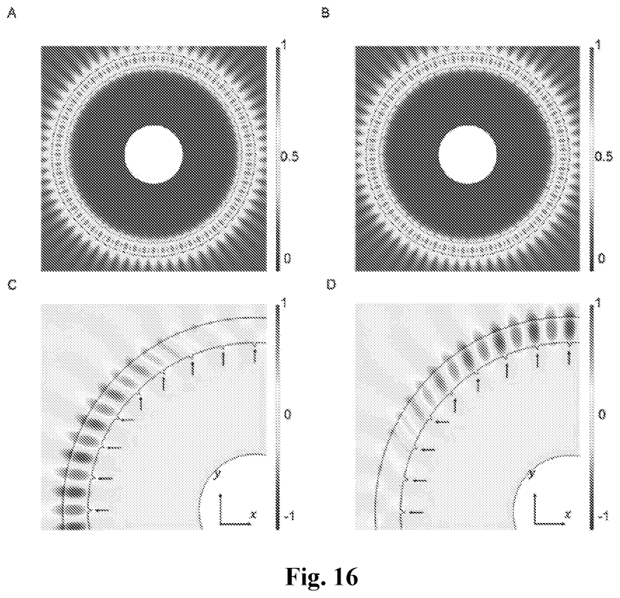

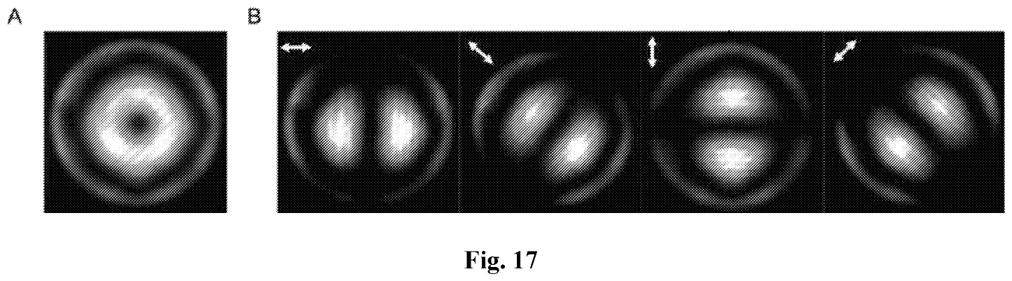

When the angular grating of order M=32 are inscribed along the inner sidewall of a single microring, the same as the order of the whispering gallery mode inside the ring designed at N=32, the single microring would emit a vortex beam with topological charge of l=±1, corresponding to the transverse spin ∓1, respectively. The degenerate clockwise and counterclockwise modes form 2 degenerate standing waves inside the ring, one with antipodes sitting at the scatterers (FIG. 16A) and the other with node at the scatterers (FIG. 16B). Considering the degenerate mode in FIG. 15A that is strongly scattered upwards by the angular grating, Eₓ and E_{y} field distributions (FIGS. 16C and 16D, respectively) of the mode indicate that the scattered field is expected to be radially polarized. With the ring geometry used in this work, it is experimentally observed that radial polarization dominates in the emitted beam (FIG. 17), which is further transferred to the emission from the arrayed laser consistent with the experimental observation in FIGS. 7D and 7E. Additionally, because of phase singularity at the center of the vortex beam, the far-field vortex emission of single rings has a doughnut shape with a dark center.

### 9. Numerical Calculated Far-Field Diffraction of High-Radiance Vortex Beams From the SUSY Microlaser Array

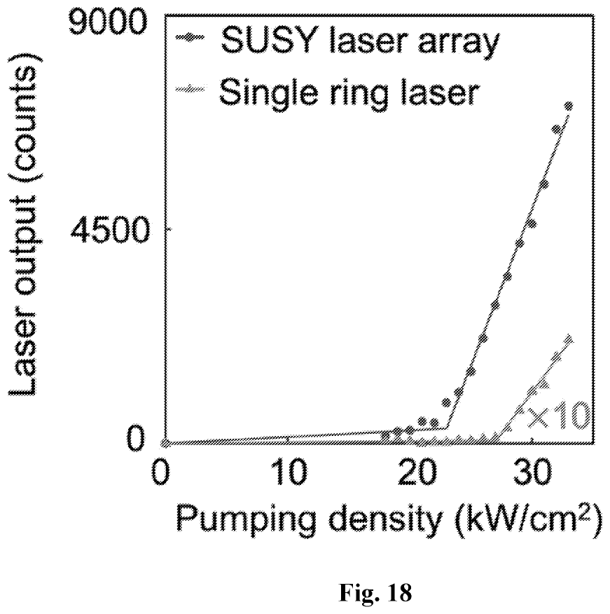

When 25 single rings emitting vortex beams form a 5×5, coupled laser array that oscillate collectively in phase, it will emit a radially polarized vortex beam with topological charges of l=±1 with the slope efficiency in its total output power enhanced by a factor of ˜20.2 compared to that of a single mirroring laser (FIG. 18).

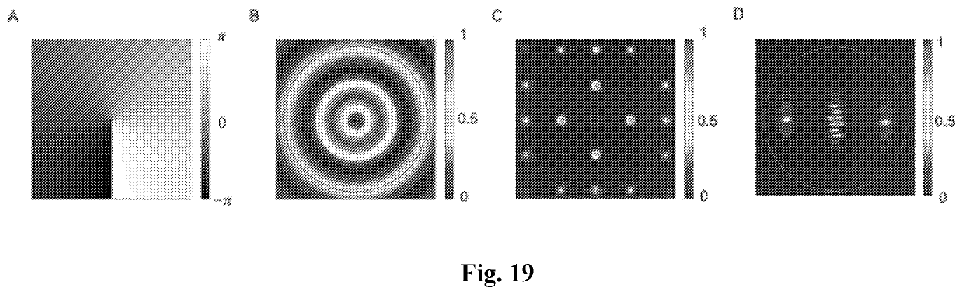

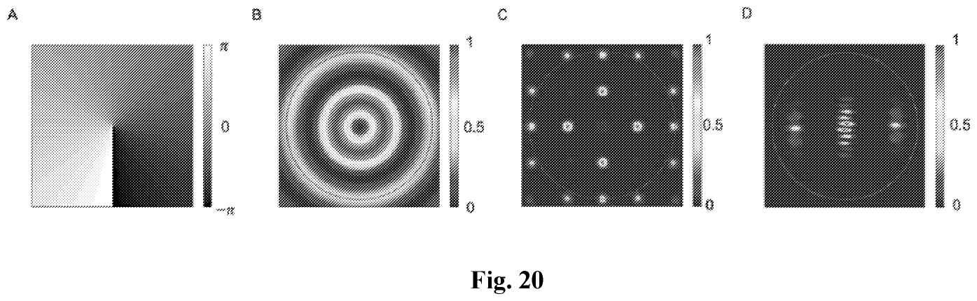

Since the far-field pattern of the SUSY microlaser array is the product of the diffraction pattern and the far-field emission of single microlasers, the phase variation of the high-radiance laser beam from the SUSY array follows that form a single microlaser (FIGS. 19A and 19B), thereby still carrying topological charges of l=±1 and a dark center. When 25 rings all with OAM+1 collectively oscillate in phase, the far-field pattern is calculated as shown in FIG. 19C. In addition, the far-field pattern has a global phase distribution corresponding to OAM+1. By placing a cylindrical lens right after the far-field pattern, 1D Fourier transform of the far-field (FIG. 19D) can be conducted and by observing the configuration of the bright spots, the global OAM+1 phase distribution can be verified (see Section 10 for details). Similar calculations of OAM−1 are conducted as shown in FIG. 20.

### 10. Higher-Dimensional Supersymmetric Microlaser Arrays

The nonlinear scaling of complexity with the increased number of components in integrated photonics is a major obstacle impeding large-scale phase-locked laser arrays. As discussed herein, a higher-dimensional supersymmetry formalism for precise mode control and nonlinear power scaling has been developed. Supersymmetric microlaser arrays feature phase-locked coherence and synchronization of all the evanescently coupled microring lasers, collectively oscillating in the fundamental transverse supermode, which enables high-radiance, small-divergence, and single-frequency laser emission with two-orders of magnitude enhancement in energy density. The present invention also demonstrates the feasibility of structuring high-radiance vortex laser beams, which enhances the laser performance by taking full advantage of spatial degrees of freedom of light. The approaches discussed herein provide a route for designing large-scale integrated photonic systems in both classical and quantum regimes.

Rapid development of integrated photonics, with continuous effort to push the limit of integration density, offers a solution to future scaling of integrated photonic networks and devices. However, the wave nature of light gives rise to fundamentally inevitable mutual coupling between photonic elements closely packed in an array. Control of mutual coupling is thus the key to phase-locking of all the elements and further driving them to function collectively. For instance, coherence and synchronization are critical for high-radiance optical emitters and lasers, as the radiance scales with the number of elements only if they are mutually coherent (1, 2). Integrated high-radiance sources including synchronized lasers arrays (1-9) and photonic crystal lasers (10, 11) are highly demanded and actively pursued for a wide range of applications, including optical communication, optical sensing, and LIDAR ranging. Among various strategies developed to enforce mutual coherence between laser resonators, the evanescent wave coupling based strategy, leveraging strong optical confinement (such as micro/nano-scale resonators and waveguides) and operating in the deep subwavelength regime, is approaching the limit of integration density. A key drawback of evanescent wave coupling is its intrinsically associated energy splitting, leading to complex mode competition and thus energy inefficiency and irregular, chaotic radiation. The alternative approaches, including antiguided, diffractive, and antenna coupling (3-6), require delicately designed “leakage” of optical modes to communicate between elements ultimately limiting their downsizing and dense packaging as well. Here, a formalism is demonstrated based on higher-dimensional supersymmetry (SUSY) to enforce phase-locking and to enable coherent oscillation in a two-dimensional (2D) laser array of evanescently coupled microlasers, opening new avenues for the realization of integrated high-radiance sources, while maintaining individual controllability of each microlaser.

SUSY was first introduced in string and quantum field theory to unify all physical interactions in nature including strong, electroweak, and gravitational coupling (12). Despite awaiting experimental validation in particle physics, the mathematic framework of SUSY has found its applications in many other branches of modern physics, ranging from non-relativistic quantum mechanics and condensed matter physics (13, 14) to optics and photonics (15, 16). SUSY is particularly powerful in tailoring mutual interactions in any arbitrary lattice of evanescently coupled elements, regardless of its complexity and size. With the unbroken SUSY, for example, the lattice Hamiltonian (where couplings are represented by the off-diagonal elements) can be transformed into a new superpartner Hamiltonian with a reduced matrix dimension, sharing almost the same eigenspectrum except for the disappearance of the original fundamental mode. This characteristic has enabled a series of photonic functionalities such as effective mode control, selection, and creation (15-21), facilitating phase-locked one-dimensional (1D) laser arrays when strategically performed in a non-Hermitian photonic environment (7-9). Nevertheless, the factorization technique used in supersymmetric transformation applies only to the Hamiltonians of 1D systems (13), which limits the scalability of SUSY photonics and hinders its further promotion into higher dimensions. This limitation has been overcome and embodiments discussed herein demonstrate a generic approach to higher-dimensional supersymmetric microlaser array.

The dissipative superpartners, coupled to a 2D main laser array, enforce the evanescently coupled microlasers to phase lock and coherently oscillate in the fundamental in-phase supermode, taking the full advantage of dense integration and fulfilling the demand for integrated, high-radiance optical sources with orders of magnitude enhancement in energy density.

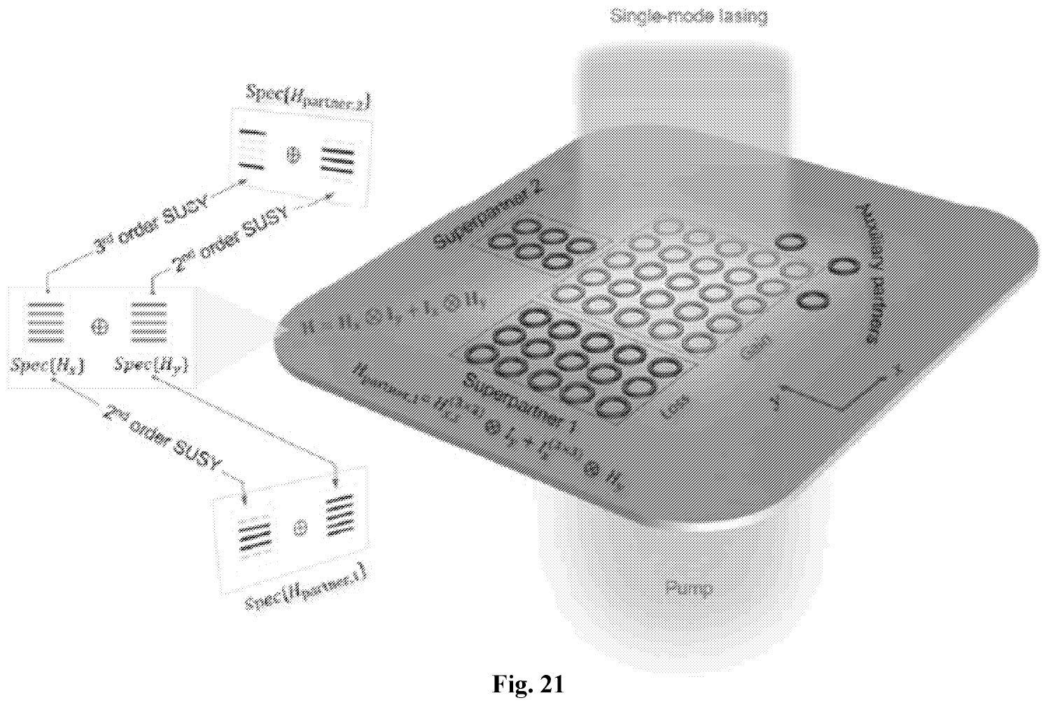

In embodiments, as illustrated in FIG. 21, a homogeneously coupled 2D array of 5×5 identical microring lasers made of InGaAsP multiple quantum wells. Considering the evanescent wave coupling between only the nearest neighbors, the main microlaser array can be represented by a tight-binding Hamiltonian,

H=−Σ_{m,n}(κₓα_{m+1,n}^{†}α_{m,n}+κ_{y}α_{m,n+1}^{†}α_{m,n}+h. c.) (1)

where κ_{x,y} denote the nearest-neighbor coupling coefficient between adjacent microrings along the x and y directions, respectively, (m, n) labels the microring sites in the (x, y) plane, α(α^{†}) is the photon annihilation (creation) operator of the resonant modes in individual microrings, and h.c. denotes the Hermitian conjugate, leading to 25 transverse supermodes with 13 closely spaced eigen-frequencies (FIG. 1) (22). Despite many transverse supermodes, the objective is to facilitate high-radiance single-frequency lasing in 2D with collective in-phase oscillation in only the fundamental transverse mode, while suppressing all other supermodes.

A generic approach has been developed to derive the isospectral superpartners of higher-dimensional tight-binding potentials, though the SUSY-based factorization technique is 1D constrained. The orthogonality inherently associated with the tight-binding potential in Eq. (1) allows for separation of variables in the potential profile, so the Hamiltonian can be described in the form of a Kronecker sum,

H=Hₓ⊕H_{y}=Hₓ⊗I_{y}+Iₓ⊗H_{y} (2)

where ⊕ and ⊗ denotes the Kronecker sum and the tensor (Kronecker) product between matrices and H_{x,y} represent 1D systems, consisting of 5 coupled resonators along the x and y direction with coupling strength κₓ and κ_{y}, and I_{y,x} are 5×5 identity matrices (22). Here, the 2D isospectral superpartners can be configured using the tensor product based on two superpartners of Hₓ and H_{y}. Specifically, in contrast to non-negligible onsite frequency detuning across the superpartner array resulting from the first-order SUSY transformation (8), applied is the second-order SUSY transformation that can yield a homogeneous superpartner array respecting the particle-hole symmetry and thus consisting of identical elements with the same resonant frequency compared with the main array (9), which is experimentally favorable especially for a large-scale system. To create a symmetric spectrum for the superpartner, in the second-order SUSY transformation two levels with the highest and lowest frequencies in the 1D Hamiltonian are eliminated (i.e., the matrix dimension of the SUSY partner of H_{x,y} reduces from 5×5 to 3×3 in the present case). The SUSY transformation thus leads to two superpartner arrays (22): a 3×5 array with 15 transverse modes corresponding to H_{partner,1}=H_{x,s}^{(3×3)}⊗Iₓ=Iₓ^{(3×3)}⊗H_{y}, where H_{x,s} is the second-order SUSY transformation of Hₓ; and a 2×3 array with 6 transverse modes corresponding to H_{partner,2}=H_{x,r}^{(2×2)}⊗I_{y}^{(3×3)}+Iₓ^{(2×2)}⊗H_{y,s}^{(3×3)}, where H_{y,s} is the second-order SUSY transformation of H_{y} and H_{x,r} (the “residual”) is an arbitrary 2×2 Hamiltonian that is isospectral to the energy levels originally in Hx, but eliminated in achieving H_{x,s}.

H_{x,r} can also be generated by a third-order SUSY transformation of Hₓ by deleting three modes apart from the first and last mode (22). Superscripts denote the dimensions of the matrices, not to be confused with the size of the resonator array. Together with 3 individual auxiliary partner microrings (2 out of 3 have zero relative frequency detuning and the frequency of the last one matches the out-of-phase supermode with the highest relative frequency among all 25 transverse modes), the spectrum of superpartners is identical to the main array apart from the fundamental in-phase supermode (FIG. 3) (22). Strategically controlled coupling of the main array with its dissipative superpartners and auxiliary partner microrings, by matching both the eigen-frequencies and mode distributions (FIG. 5), therefore ensures the suppression of all but the fundamental transverse supermode, yielding efficient single-supermode lasing.

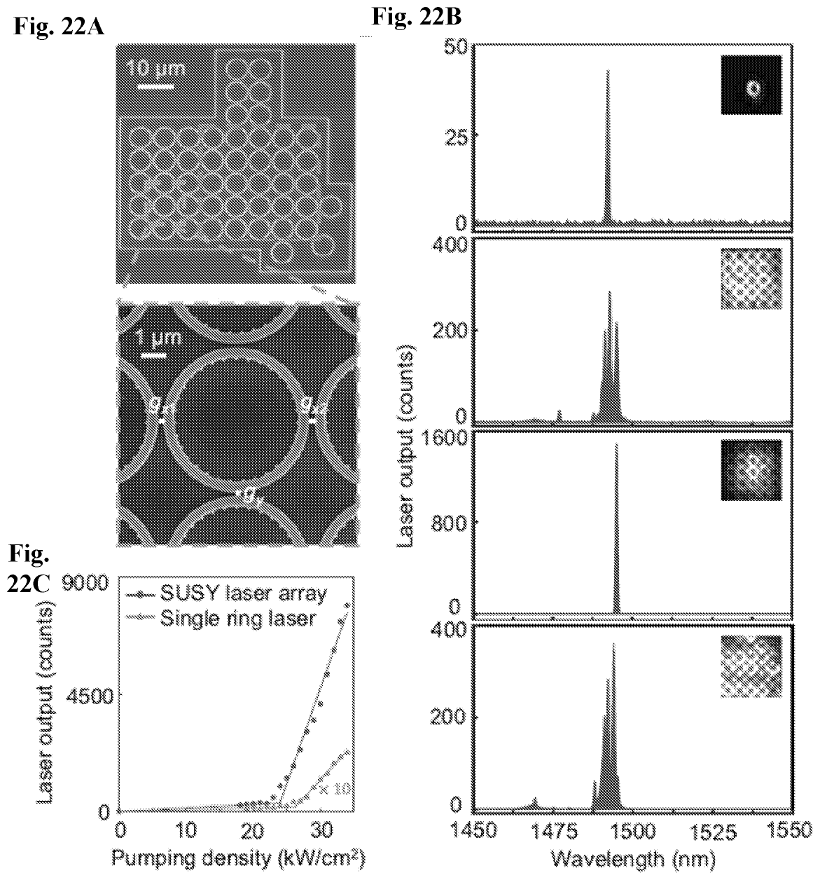

The scanning electron microscope (SEM) images of the SUSY array sample fabricated on 200 nm thick InGaAsP multiple quantum wells (22) are shown in FIG. 2A. The microring resonators were patterned with an inner radius of 3 um and the width of the waveguide of 400 nm, operating at a resonance order of N=32 for the quasi-TE mode. To facilitate surface emission from mirroring lasers, an angular grating was inscribed on the inner sidewall of each mirroring. Emission from each scatterer in the angular grating is circularly polarized, resulting from the transverse spin in the evanescent region of the waveguide (i.e., the azimuthal and radial electric field components have π/2 phase difference) (23, 24). With the transverse spin (|s|=1), the order of the angular grating are designed as M=N−1=31, creating phase matching for equi-phase emission from all the scatterers on a mirroring carrying an orbital angular momentum (OAM) of 1=0. The emission spectrum of the SUSY microlaser array was characterized in addition to emission spectra from three control experiments (FIG. 22B), all pumped optically by a nanosecond pulsed laser at the wavelength of 1064 nm (22). Although a single microlaser operates with the designed single-mode laser action, evanescent couplings between microlasers in a 5×5 array with the Hamiltonian in Eq. (1) cause energy splitting with a multimode spectrum centered at the resonance frequency of a single microlaser. In the SUSY microlaser array, selective uniform pumping of the main array with gradual intensity decay extending to its surroundings results in high-power single-frequency lasing in the fundamental transverse supermode.

In this manner, the superpartners are pumped below the lasing threshold so still remain dissipative, while the gain-loss contrast between the main array and superpartners is sufficiently low to maintain efficient couplings between them, which is equivalent to a system operating in the parity-time symmetric phase (22, 25, 26). The global mode matching with dissipative superpartners ensures suppression of all but the fundamental supermode, leading to high-radiance single-frequency lasing with significant power enhancement. The importance of the dissipative superpartners was convincingly validated by the control experiment in which the entire SUSY microlaser array (including both the main array and superpartners) was uniformly pumped at the same pumping intensity. Emission collected from the main array shows a multimode spectrum similar to the 5×5 array in terms of the frequencies of lasing peaks with slight power variations. In the in-phase transverse supermode, all 25 individual microlasers in the main array oscillate and contribute to power enhancement with a factor of ˜25 with respect to emission from a single microlaser, as evidently shown by the light-light curves where the slope efficiency of the SUSY microlaser array is 26.3 times higher than that of a single microlaser (FIG. 22C). Additionally, the SUSY microlaser array also exhibits a lower lasing threshold because of better optical modal overlap with the gain material.

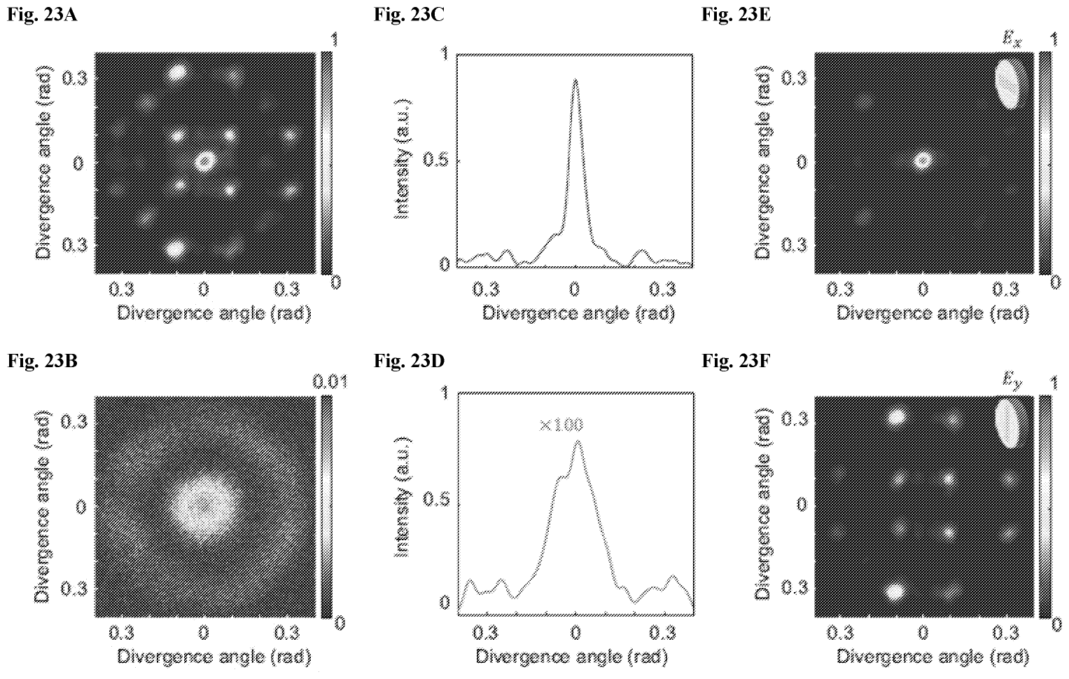

Beyond power enhancement, the major virtue of the higher-dimensional in-phase supermode lasing is the strong 2D concentration of its emission in the far field, with ultimate energy density quadratically growing with the number of arrayed microlasers. The far-field pattern of the laser beam is a product of far-field diffraction of the supermode and single microlaser emission (FIG. 23A). As the designed angular grating meets the condition for equi-phase emission (l=0), emissions from all scatterers in the single ring add constructively at the center of the far field as they carry the same polarization (FIG. 23B) (22). Specifically, the laser radiation from the 2D SUSY microlaser array exhibits beam divergence of ˜2°, compared to a single microlaser of ˜11°. The combination of power enhancement and narrower divergence results in two orders of magnitude enhancement in energy density (FIGS. 23C and 23D). Note that each mirroring supports two degenerate modes (clockwise and counterclockwise circulating modes or their hybridized interfering modes), so each transverse supermode, including the fundamental transverse supermode, carries a twofold degeneracy that both contribute to laser actions (22). Due to the two degenerate modes being spatially offset by a phase of π/2, their associated fields are x- and y-polarized as a result from two orthogonal superpositions of the two opposite transverse spins carried by clockwise and counterclockwise modes, respectively. Therefore, the two degenerate modes, leading to different diffraction patterns, can be distinguished by selective measurements of the two polarization states (FIGS. 23E and 23F). Only the mode with the x polarization, for its in-phase characteristic, contributes to the zero-order diffraction and energy concentration at the center.

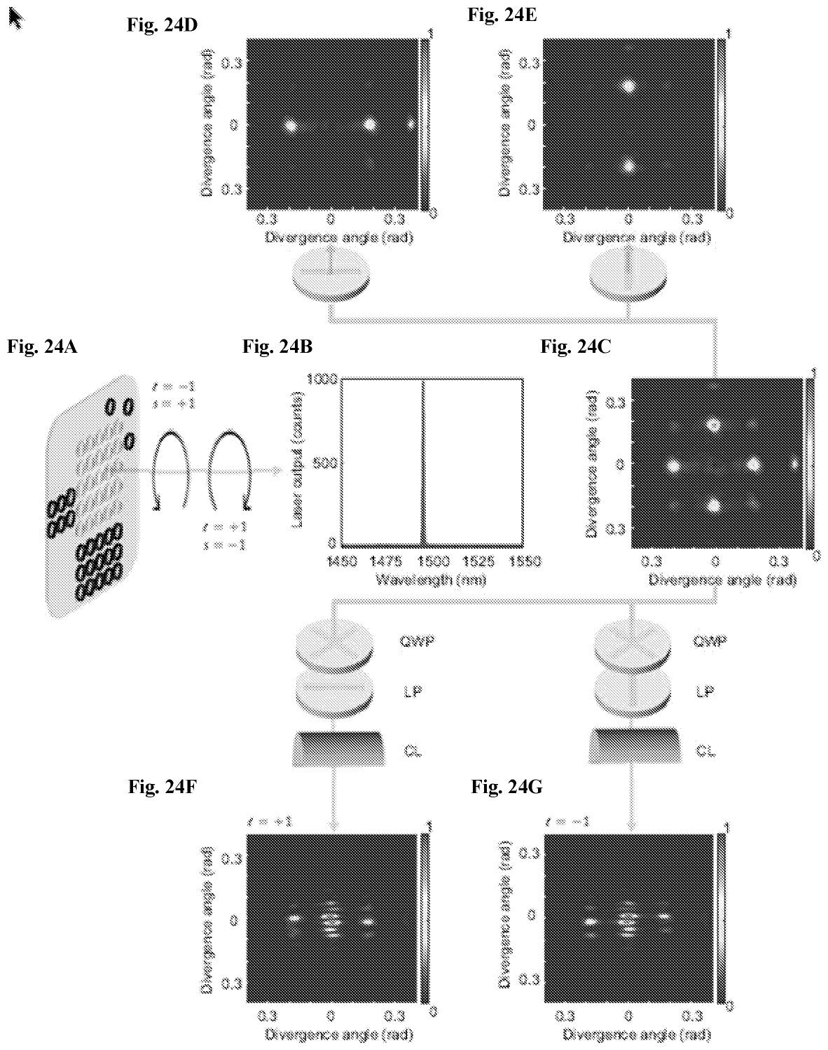

It has been recently demonstrated that single microrings offer a convenient strategy for the generation of structured light with spatially inhomogeneous phase variation and polarization distribution, such as optical vortices (23, 24, 27). Another feature of the higher-dimensional SUSY microlaser array is to maintain the vectorial nature of structured light, while improving the total power output. By matching the order of the angular grating with the order of the resonant mode (i.e., M=N=32), the total angular momentum associated with emission becomes zero, leading to the nonzero OAM of l=±1 spin-orbit-locked with transverse spins of s=∓1 associated with the counterclockwise and clockwise modes in every microring, respectively (FIG. 24A). The desired phase variation and polarization distribution are collectively transferred to the laser beam emitted from the SUSY microlaser array, thereby facilitating single-frequency high-radiance vortex lasing with a factor of 20.2 in power enhancement (FIG. 24B). Because of the phase singularity at the center of the vortex beams, energy is mainly redistributed to the first and second diffraction orders of the in-phase supermode in the far field (FIG. 24C). The phase fronts of the two vortex beams wind in opposite azimuthal directions, which creates the superposition of left and right handed circularly polarized fields with a continuously varying phase delay between them, leading to a vector beam with radial polarizations (22): along the horizontal axis, the phase delay is 0, resulting in the x-polarized field, whereas the phase delay becomes ±π in the vertical axis, corresponding to the y-polarized field (FIGS. 24D and 24E). The two vortex beams with opposite spin-orbit relations can be effectively separated using appropriate combinations of a quarter wave plate and a linear polarizer. Their associated topological charges corresponding to the OAM was characterized by performing 1D Fourier transform of the two vortex beams using a cylindrical lens (FIGS. 24G and 24F) (28). Such astigmatic transformation yields strongly deformed vortices at the focal spot with destructive interference across the 1D diffraction pattern (22). Only one dark fringe is clearly observed in the center area, confirming the topological charge of OAM light of l=±1. The orientations of the fringe with respect to the horizontal axis are correlated with the signs of the topological charges.

The supersymmetric microlaser arrays efficiently produce high-radiance, small-divergence laser beams with orders of magnitude enhancement in energy density. Developing SUSY principles into higher dimensions constitutes a powerful toolbox for effectively tailoring evanescent wave couplings in a large-scale photonic array to synchronize densely packed array elements and prescribe the desired oscillating supermode. Such strategy is generic and applicable to various platforms, for example coupled vertical-cavity surface-emitting lasers (2) or coupled nano-lasers (29, 30). Additionally, both phase front and polarization of laser radiation can be spatially structured, taking full advantage of spatial degrees of freedom for deployment in the next generation classical and quantum integrated photonic systems.

Further referencing the Figures, FIG. 21 illustrates and exemplary higher-dimensional supersymmetric microlaser array, consisting of a 5×5 main array of evanescently coupled microring lasers (red), coupled with its 2 dissipative superpartner arrays and 3 auxiliary partner microrings (blue). The second-order SUSY transformation on Hₓ yields its SUSY partner H_{x,s}^{(3×3)}, a 3×3 matrix denoting the coupling strengths in superpartner 1 in the x direction, which is isospectral to Hₓ except for the highest and lowest energy levels. Kronecker sum between H_{x,s}^{(3×3)} and the unvaried H_{y} generates the Hamiltonian of superpartner 1, corresponding to an array of 3×5 coupled microrings. Similarly, a third-order SUSY transformation on Hₓ and a second-order SUSY transformation on H_{y} yields the Hamiltonian of superpartner 2, H_{partner,2}=H_{x,r}^{(2×2)}⊕_{K}H_{y,s}^{(3×3)}, corresponding to a 2×3 array. 3 auxiliary partner microrings are introduced to couple to 3 out of 4 remaining energy levels of H (22). Altogether, dissipative supersymmetric and auxiliary partners are isospectral to the main array except for the lowest energy level associated with the fundamental transverse supermode, suppressing all the higher-order transverse supermodes but facilitating a high-radiance single-mode laser action operating exclusively on the fundamental in-phase supermode.

FIG. 22 illustrates an experimental characterization of the higher dimensional supersymmetric microlaser array. FIG. 22A shows SEM images of the SUSY microlaser array. The main array is denoted by the red box, where uniform evanescent couplings are introduced with a gap of 200 nm between any pair of adjacent rings. The supersymmetric and auxiliary partners are placed in the proximity to the main array with a gap of 330 nm. The zoom-in image shows detailed couplings in superpartner array 1: varying coupling strengths with a gap of gₓ₁=240 nm and the other gₓ₂=300 nm in the x direction and uniform coupling equal to that in the main array with a gap of g_{y}=200 nm in the y direction.

FIG. 22B shows emission spectra, from top to bottom, of a single microring laser (single frequency lasing at 1492 nm), a 5×5 array of microring lasers with identical design parameters but no coupled supersymmetric and auxiliary partners, the supersymmetric microlaser array coupled with dissipative partners by selective pumping (single frequency lasing at 1495 nm), and the supersymmetric microlaser array but with uniform pumping on both the main array and partners, respectively, at the same pumping intensity of 32 kW/cm². SUSY laser array lases in the longest wavelength mode among all the supermodes in the 5×5 array, confirming it is the fundamental supermode. In the two measurements for the SUSY array, only the emission from the main array is collected for a fair comparison. The insets show the corresponding emission images at the sample plane, where intensity distribution associated with the selectively pumped SUSY laser array also confirms its operation in the fundamental supermode.

FIG. 22C shows a light-light curve showing the lowering of the threshold and enhancement of lasing output (the slope efficiency) in the SUSY microlaser array compared to a single mirroring laser. The laser output of the single mirroring laser is magnified by 10 times for better visualization.

FIG. 23. Far-field characterization of laser emission from the higher-dimensional supersymmetric microlaser array. FIGS. 23A and 23B are far-field diffraction patterns of laser emissions from the SUSY microlaser array and a single mirroring laser, respectively. FIGS. 23C and 23D are the corresponding intensity distribution of laser emissions from the SUSY microlaser array and single mirroring laser, respectively, both along the x axis, showing small divergence of ˜2° (vs. divergence of ˜11° for the single microlaser) and energy concentration with 2 orders of magnitude enhancement in intensity associated with the laser beam from the SUSY microlaser array. Lasing intensity in 23D is magnified by 100 times for better visualization. FIGS. 23E and 23F correspond to x- and y-polarized diffraction patterns of emission from the SUSY microlaser array, respectively, arising from the two degenerate modes in microrings while both oscillating in the fundamental transverse mode.

FIG. 24. Generation of high-radiance structured light. FIG. 24A shows the SUSY microlaser array can produce vortex beams by strategically designing the angular grating inscribed on each mirroring. With M=N=32, where M and N are the orders of the angular grating and the resonant mode of the microrings, two vortex beams with the OAM of l=±1 spin-orbit-locked with transverse spins of s=∓1 are simultaneously excited, arising from the degenerate clockwise and counterclockwise circulating modes in microrings, respectively. FIG. 24B shows a single-frequency lasing of vortex emission at 1495 nm. FIG. 24C shows the far field diffraction pattern of vortex emission, corresponding to the superposition of two vortex beams. Due to the phase singularity at the center of vortex beams, a dark center is observed with energy mainly distributed in the first and second diffraction orders. FIGS. 24D and 24E are x- and y-polarized diffraction patterns of superimposed vortex emissions, showing radially polarized vortex beams. FIGS. 24F and 24G are the 1D diffraction pattern of the two distinct vortex beams of l=±1, respectively, filtered by the combined quarter wave plate (QWP) and linear polarizer (LP. The 1D diffraction pattern, equivalent to the 1D Fourier transform of the far-field pattern in FIG. 24C along the y direction, is captured at the focal plane of a cylindrical lens (CL).

### Aspects

The following Aspects are illustrative only and do not serve to limit the scope of the present disclosure or the appended claims.

Aspect 1. A single-mode, high power optical system, comprising: a main array of light sources resonating with a plurality of energy levels, the plurality of energy levels including a fundamental mode; at least one superpartner array of optical resonators positioned adjacent to the main array, the at least one superpartner array of optical resonators configured to at least partially dissipate a subset of the plurality of energy levels emitted by the main array, wherein each subset does not include the fundamental mode; and at least one auxiliary optical resonator configured to further dissipate any remaining energy levels except for the fundamental mode.

Aspect 2. The system of Aspect 1, wherein the main array of light sources is an N×x N array.

Aspect 3. The system of Aspect 2, wherein the main array of light sources is a 5×5 array.

Aspect 4. The system of any one of Aspects 1-3, comprising two superpartner arrays and three auxiliary optical resonators.

Aspect 5. The system of Aspect 4, wherein a combination of the at least one superpartner array and the at least one auxiliary optical resonator match eigenfrequencies and mode distributions of the main array.

Aspect 6. The system of any one of Aspects 1-5, wherein a combination of the at least one superpartner array and the at least one auxiliary optical resonator match eigenfrequencies and mode distributions of the main array.

Aspect 7. The system of any one of Aspects 1-6, comprising three auxiliary optical resonators, wherein two of the three auxiliary optical resonators have zero relative frequency detuning, and a frequency of the third auxiliary optical resonators matches an out-of-phase supermode with a highest relative frequency among the plurality of energy levels.

Aspect 8. The system of any one of Aspects 1-7, wherein the subset of the plurality of energy levels is determined by applying a supersymmetry transformation on the main array of light sources.

Aspect 9. The system of any one of Aspects 1-8, wherein the light sources are lasers.

Aspect 10. The system of Aspect 9, wherein the light sources are at least one of micro-ring lasers electrically-injected lasers.

Aspect 11. The system of any one of Aspects 1-10, wherein light sources of the main array have and optical resonators in the at least one superpartner array comprises have a same resonance frequency.

Aspect 12. The system of Aspect 11, wherein the auxiliary optical resonators have different frequencies than the resonance frequency of the light sources of the main array and the optical resonators of the at least one superpartner array.

Aspect 13. A method for emitting a single-mode, high power optical signal, comprising: resonating with a plurality of energy levels, including a fundamental mode, in a main array of light sources; at least partially dissipating a subset of the plurality of energy levels in resonance in the main array with at least one superpartner array of optical resonators positioned adjacent to the main array, wherein the subset of the plurality of energy levels does not include the fundamental mode; further dissipating any remaining energy levels, except the fundamental mode, using at least one auxiliary optical resonator.

Aspect 14. The method of Aspect 13, wherein the light sources are lasers.

Aspect 15. The method of any one of claims 13-14, wherein the light sources comprise at least one of: micro-ring lasers and electrically-injected lasers

Aspect 16. The method of any one of claims 13-15, further comprising determining the subset of the plurality of energy levels by applying a supersymmetry transformation on the main array of light sources.

Aspect 17. The method of Aspect 16, further comprising determining any remaining energy levels by applying a supersymmetry transformation on the at least one superpartner array.

Aspect 18. The method of any one of Aspects 13-17, further comprising matching eigenfrequencies and mode distributions of the main array using a combination of the at least one superpartner array and the at least one auxiliary optical resonator.

Aspect 19. The method of Aspect 18, comprising matching a frequency of an auxiliary optical resonator with an out-of-phase supermode having a highest relative frequency among the plurality of energy levels using at least one auxiliary optical resonator.

Aspect 20. The method of any one of Aspects 13-19, wherein two superpartner arrays dissipate the subset of the plurality of energy levels.

Aspect 21. The method of Aspect 20, wherein modes of the main array correspond to:

H=Hₓ⊕H_{y}=Hₓ⊕I_{y}+Iₓ⊕H_{y};
modes of a first superpartner array correspond to:

H_{partner,1}=H_{x,s}^{(3×3)}⊗Iₓ=Iₓ^{(3×3)}⊗H_{y},

wherein H_{x,s} is a second-order transformation of Hₓ; and modes of a second superpartner array correspond to:

H_{partner,2}=H_{x,r}^{(2×2)}⊗I_{y}^{(3×3)}+Iₓ^{(2×2)}⊗H_{y,s}^{(3×3)},

where H_{y,s} is a second-order transformation of H_{y} and H_{x,r} is a Hamiltonian that is isospectral to energy levels in Hₓ.

Aspect 22. The method of Aspect 13, further comprising applying the fundamental mode to at least one of: a Light Detection and Ranging (LIDAR) system, an optical communication system, and a 3D sensing system.

Aspect 23. The method of claim 13, wherein one or more of the at least one superpartner array and at least one auxiliary optical resonators are electrically pumped or optically pumped to prevent decoupling from the main array.

Aspect 24. A single-mode, high power optical system, comprising: a main array of light sources resonating with a plurality of energy levels, the plurality of energy levels including a fundamental mode; at least one superpartner array of optical resonators positioned adjacent to the main array, the at least one superpartner array of optical resonators configured to at least partially dissipate a subset of the plurality of energy levels emitted by the main array, wherein each subset does not include the fundamental mode.

Aspect 25. A single-mode, high power optical system, comprising: a main array of light sources resonating with a plurality of energy levels, the plurality of energy levels including a fundamental mode; at least one optical resonator positioned separately and adjacent to the main array, the at least one optical resonator configured to at least partially dissipate a subset of the plurality of energy levels emitted by the main array, wherein each subset does not include the fundamental mode.

### REFERENCES

1. D. Botez, D. R. Scifres, Diode Laser Arrays (Cambridge University Press, 2005).

2. D. F. Siriani, K. D. Choquette, “Coherent Coupling of Vertical-Cavity Surface-EmittingLaser Arrays” in Semiconductors and Semimetals, J. J. Coleman, A. C. Bryce, C. Jagadish, Eds. (Elsevier, 2012), vol. 86, chap. 6.

3. J. R. Leger, M. L. Scott, W. B. Veldkamp, Coherent addition of AlGaAs lasers using microlenses and diffractive coupling. Appl. Phys. Lett. 52, 1771-1773 (1988).

4. D. Botez, L. Mawst, P. Hayashida, G. Peterson, T. J. Roth, High-power, diffraction-limited-beam operation from phase-locked diode-laser arrays of closely spaced ‘“leaky”’ waveguides (antiguides). Appl. Phys. Lett. 53, 464-466 (1988).

5. D. F. Siriani, K. D. Choquette, Implant defined anti-guided vertical-cavity surface-emitting laser arrays. IEEE J. Quantum Electron. 47, 160-164 (2011).

6. T.-Y. Kao, J. L. Reno, Q. Hu, Phase-locked laser arrays through global antenna mutual coupling. Nat. Photonics. 10, 541-546 (2016).

7. R. El-Ganainy, L. Ge, M. Khajavikhan, D. N. Christodoulides, Supersymmetric laser arrays. Phys. Rev. A. 92, 033818 (2015).

8. M. P. Hokmabadi, N. S. Nye, R. El-Ganainy, D. N. Christodoulides, M. Khajavikhan, Supersymmetric laser arrays. Science. 363, 623-626 (2019).

9. B. Midya, H. Zhao, X. Qiao, P. Miao, W. Walasik, Z. Zhang, N. M. Litchinitser, L. Feng, Supersymmetric mirroring laser arrays. Photon. Res. 7, 363-367 (2019).

10. M. Yoshida, M. De Zoysa, K. Ishizaki, Y. Tanaka, M. Kawasaki, R. Hatsuda, B. Song, J. Gelleta, S. Noda, Double-lattice photonic-crystal resonators enabling high-brightness semiconductor lasers with symmetric narrow-divergence beams. Nat. Mater. 18, 121-128 (2019).

11. A. Kodigala, T. Lepetit, Q. Gu, B. Bahari, Y. Fainman, B. Kante, Lasing action from photonic bound states in continuum. Nature 541, 196-199 (2017).

12. M. Dine, Supersymmetry and String Theory: Beyond the Standard Model (Cambridge University Press, 2007).

13. F. Cooper, A. Khare, U. Sukhatme, Supersymmetry and quantum mechanics. Phys. Rep. 251, 267-385 (1995).

14. N. Sourlas, Introduction to supersymmetry in condensed matter physics. Physica D 15, 115-122 (1985).

15. M-A. Miri, M. Heinrich, R. El-Ganainy, D. N. Christodoulides, Supersymmetric Optical Structures. Phys. Rev. Lett. 110, 233902 (2013).

16. M. Heinrich, M.-A. Miri, S. Stutzer, R. El-Ganainy, S. Nolte, A. Szameit, D. N. Christodoulides, Supersymmetric mode converters. Nat. Commun. 5, 3698 (2014).

17. S. Longhi, Invisibility in non-Hermitian tight-binding lattices. Phys. Rev. A. 82, 032111 (2010).

18. M. Heinrich, M.-A. Miri, S. Stutzer, S. Nolte, D. N. Christodoulides, A. Szameit, Observation of supersymmetric scattering in photonic lattices. Opt. Lett. 39, 6130-6133 (2014).

19. S. Yu, X. Piao, J. Hong, N. Park, Bloch-like waves in random-walk potentials based on supersymmetry. Nat. Commun. 6, 8269 (2015).

20. W. Walasik, B. Midya, L. Feng, N. M. Litchinitser, Supersymmetry-guided method for mode selection and optimization in coupled systems. Opt. Letts. 43, 3758-3761 (2018).

21. S. Barkhofen, L. Lorz, T. Nitsche, C. Silberhorn, H. Schomerus, Supersymmetric Polarization Anomaly in Photonic Discrete-Time Quantum Walks. Phys. Rev. Lett. 121, 260501 (2018).

22. Materials, methods, and additional information are available as supplementary materials.

23. Z. Shao, J. Zhu, Y. Chen, Y. Zhang, S. Yu, Spin-orbit interaction of light induced by transverse spin angular momentum engineering. Nat. Commun. 9, 926 (2018).

24. Z. Zhang, X. Qiao, B. Midya, K. Liu, J. Sun, T. Wu, W. Liu, R. Agarwal, J. M. Jornet, S. Longhi, N. M. Litchinitser, L. Feng, Tunable topological charge vortex microlaser. Science 368, 760-763 (2020).

25. L. Feng, R. El-Ganainy, L. Ge, Non-Hermitian photonics based on parity-time symmetry. Nat. Photon. 11, 752-762 (2017).

26. B. Peng, S. K. Ozdemir, F. Lei, F. Monifi, M. Gianfreda, G. L. Long, S. Fan, F. Nori, C. M. Bender, L. Yang, Parity-time-symmetric whispering-gallery microcavities, Nat. Phys. 5, 394-398 (2014).

27. B. Bahari, L. Hsu, S. H. Pan, D. Preece, A. Ndao, A. El Amili, Y. Fainman, B. Kant6, Photonic quantum Hall effect and multiplexed light sources of large orbital angular momenta. Nat. Phys. (2021). https://doi.org/10.1038/s41567-021-01165-8.

28. S. N. Alperin, R. D. Niederriter, J. T. Gopinath, M. E. Siemens, Quantitative measurement of the orbital angular momentum of light with a single, stationary lens. Opt. Lett. 41, 5019-5022 (2016).

29. K. Takeda, T. Sato, A. Shinya, K. Nozaki, W. Kobayashi, H. Taniyama, M. Notomi, K. Hasebe, T. Kakitsuka, S. Matsuo, Few-fJ/bit data transmissions using directly modulated lambda-scale embedded active region photonic-crystal lasers. Nat. Photon. 7, 569-575 (2013).

30. S. S. Deka, S. H. Pan, Q. Gu, Y. Fainman, A. El Amili, Coupling in a dual metallo-dielectric nanolaser system. Opt. Lett. 42, 4760-4763 (2017).

1. A single-mode, high power optical system, comprising:
a main array of light sources resonating with a plurality of energy levels, the plurality of energy levels including a fundamental mode;
at least one superpartner array of optical resonators positioned adjacent to the main array, the at least one superpartner array of light sources configured to at least partially dissipate a subset of the plurality of energy levels emitted by the main array, wherein each subset does not include the fundamental mode; and
at least one auxiliary optical resonator configured to further dissipate any remaining energy levels except for the fundamental mode.

2. The system of claim 1, wherein the main array of light sources is an N×N array.

3. (canceled)

4. The system of claim 1, comprising two superpartner arrays and three auxiliary optical resonators.

5. The system of claim 4, wherein a first superpartner array is an (N−2)×N array and a second superpartner array is a 2×(N−2) array.

6. The system of claim 1, wherein a combination of the at least one superpartner array and the at least one auxiliary optical resonator match eigenfrequencies and mode distributions of the main array.

7. The system of claim 1, comprising three auxiliary optical resonators, wherein two of the three auxiliary optical resonators have zero relative frequency detuning, and a frequency of the third auxiliary optical resonators matches an out-of-phase supermode with a highest relative frequency among the plurality of energy levels.

8. The system of claim 1, wherein the subset of the plurality of energy levels is determined by applying a supersymmetry transformation on the main array of light sources.

9. The system of claim 1, wherein the light sources are lasers.

10. (canceled)

11. The system of claim 1, wherein light sources of the main array have and optical resonators in the at least one superpartner array comprises have a same resonance frequency.

12. The system of claim 11, wherein the auxiliary optical resonators have different frequencies than the resonance frequency of the light sources of the main array and the optical resonators of the at least one superpartner array.

13. A method for emitting a single-mode, high power optical signal, comprising:
resonating with a plurality of energy levels, including a fundamental mode, in a main array of light sources:
at least partially dissipating a subset of the plurality of energy levels in resonance in the main array with at least one superpartner array of optical resonators positioned adjacent to the main array, wherein the subset of the plurality of energy levels does not include the fundamental mode:
further dissipating any remaining energy levels, except the fundamental mode, using at least one auxiliary optical resonator.

14. (canceled)

15. The method of claim 13, wherein the light sources comprise at least one of: micro-ring lasers and electrically-injected lasers.

16. The method of claim 13, further comprising at least one of:
determining the subset of the plurality of energy levels by applying a supersymmetry transformation on the main array of light sources; and
determining any remaining energy levels by applying a supersymmetry transformation on the at least one superpartner array.

17. (canceled)

18. The method of claim 13, further comprising matching eigenfrequencies and mode distributions of the main array using a combination of the at least one superpartner array and the at least one auxiliary optical resonator.

19. The method of claim 18, comprising matching a frequency of an auxiliary optical resonator with an out-of-phase supermode having a highest relative frequency among the plurality of energy levels using at least one auxiliary optical resonator.

20. The method of claim 1, wherein two superpartner arrays dissipate the subset of the plurality of energy levels.

21. The method of claim 20, wherein modes of the main array correspond to:
H=Hₓ⊕H_{y}=Hₓ⊕I_{y}+Iₓ⊕H_{y};
modes of a first superpartner array correspond to:
H_{partner,1}=H_{x,s}^{(3×3)}⊗Iₓ=Iₓ^{(3×3)}⊗H_{y},
wherein H_{x,s} is a second-order transformation of Hₓ; and
modes of a second superpartner array correspond to:
H_{partner,2}=H_{x,r}^{(2×2)}⊗I_{y}^{(3×3)}+Iₓ^{(2×2)}⊗H_{y,s}^{(3×3)},
where H_{y,s} is a second-order transformation of H_{y} and H_{x,r} is a Hamiltonian that is isospectral to energy levels in Hₓ.

22. The method of claim 13, further comprising applying the fundamental mode to at least one of: a Light Detection and Ranging (LIDAR) system, an optical communication system, and a 3D sensing system.

23. The method of claim 13, wherein one or more of the at least one superpartner array and at least one auxiliary optical resonators are electrically pumped or optically pumped to prevent decoupling from the main array.

24. (canceled)

25. A single-mode, high power optical system, comprising:
a main array of light sources resonating with a plurality of energy levels, the plurality of energy levels including a fundamental mode;
at least one optical resonator positioned separately and adjacent to the main array, the at least one optical resonator configured to at least partially dissipate a subset of the plurality of energy levels emitted by the main array, wherein each subset does not include the fundamental mode.
